(19) United States
(12) Patent Application Publication
(10) Pub. No.: US 2026/0177907 A1
(43) Pub. Date: Jun. 25, 2026

(54) DUMMY IMPRINTED REGIONS

(71) Applicant: Magic Leap, Inc., Plantation, FL (US)

(72) Inventors: Qizhen XUE, Austin, TX (US); Vikramjit SINGH, Pflugerville, TX (US); Frank Y. XU, Plantation, FL (US)

(21) Appl. No.: 19/128,556

(22) PCT Filed: Dec. 1, 2023
(86) PCT No.: PCT/US2023/082041

§ 371 Date: May 8, 2025

Related U.S. Application Data
(60) Provisional application No. 63/429,434, filed on Dec. 1, 2022.

(51) Int. Cl. G03F 7/00

(52) U.S. Cl. CPC G03F 7/0002

(57) ABSTRACT

In some implementations, a method includes imprinting an optically-diffractive structure, and imprinting an optically-sub-diffractive structure adjacent to the optically-diffractive structure. For example, the structures can be grating with different characteristics. The imprinted structures can be included in optical devices and display systems.

### CROSS-REFERENCE TO RELATED APPLICATIONS

This application claims priority to U.S. Provisional Ser. No. 63/429,434, filed on Dec. 1, 2022, the entirety of which is incorporated herein by reference.

### FIELD OF THE DISCLOSURE

The present disclosure relates to imprinting processes and structures, such as for optical devices.

### BACKGROUND

Modern computing and display technologies have facilitated the development of systems for so-called “virtual reality” or “augmented reality” experiences, in which digitally reproduced images or portions thereof are presented to a user in a manner such that they seem to be, or may be perceived as, real. A virtual reality, or “VR”, scenario typically involves presentation of digital or virtual image information without transparency to other actual real-world visual input; an augmented reality, or “AR”, scenario typically involves presentation of digital or virtual image information as an augmentation to visualization of the actual world around the user. A mixed reality, or “MR”, scenario is a type of AR scenario and typically involves virtual objects that are integrated into, and responsive to, the natural world. For example, in an MR scenario, AR image content may be blocked by or otherwise be perceived as interacting with objects in the real world.

Referring to FIG. 1, an augmented reality scene 10 is depicted in which a user of an AR technology sees a real-world park-like setting 20 featuring people, trees, buildings in the background, and a concrete platform 30. In addition to these items, the user of the AR technology also perceives that he “sees” “virtual content” such as a robot statue 40 standing upon the real-world platform 30, and a cartoon-like avatar character 50 flying by which seems to be a personification of a bumble bee, even though these elements 40, 50 do not exist in the real world. Because the human visual perception system is complex, it can be challenging to produce an AR technology that facilitates a comfortable, natural-feeling, rich presentation of virtual image elements amongst other virtual or real-world imagery elements.

Systems and methods disclosed herein address various challenges related to AR and VR technology. Imprinting processes, such as nanoimprint lithography (NIL), can be used to form optical structures such as diffraction gratings and other diffractive optical elements. Imprinted optical structures can be used in AR, VR, and other technology.

### SUMMARY

Some aspects of this disclosure describe a method that includes imprinting an optically-diffractive structure, and imprinting an optically-sub-diffractive structure adjacent to the optically-diffractive structure.

This and other methods discussed herein can have one or more of at least the following characteristics.

In some implementations, the optically-diffractive structure includes a first grating, and the optically-sub-diffractive structure includes a second grating. At least one geometrical feature differs between the first grating and the second grating.

In some implementations, the at least one geometrical feature includes at least one of grating orientation, pitch, width, height, or duty cycle.

In some implementations, the second grating includes features that extend parallel to a separation direction of the imprinting.

In some implementations, the optically-sub-diffractive structure includes multiple different structures in respective zones of a plurality of zones of the optically-sub-diffractive structure.

In some implementations, the multiple different structures are different in at least one of feature density or feature orientation.

In some implementations, the plurality of zones are arranged along an imprint direction.

In some implementations, wherein the optically-sub-diffractive structure surrounds the optically-diffractive structure.

In some implementations, the optically-sub-diffractive structure includes features having a gradated dimension, the gradated dimension increasing or decreasing in a direction toward the optically-diffractive structure.

In some implementations, the features includes grating walls having heights that increase in the direction toward the optically-diffractive structure.

In some implementations, the optically-sub-diffractive structure includes features having a gradated dimension, the gradated dimension increasing or decreasing in an imprint direction.

In some implementations, imprinting the optically-diffractive structure and imprinting the optically-sub-diffractive structure are performed in a common imprinting process using a common template.

In some implementations, the optically-diffractive structure includes a diffractive in-coupler to a waveguide or a diffractive out-coupler from the waveguide.

In some implementations, the optically-sub-diffractive structure includes features extending circumferentially around the optically-diffractive structure.

In some implementations, the optically-diffractive structure has a pitch between 200 nm and 1 μm, and the optically-sub-diffractive structure has a pitch between 20 nm and 200 nm.

In some implementations, the optically-diffractive structure has a pitch that causes the optically-diffractive structure to interact diffractively with visible light, and the optically-sub-diffractive structure has a pitch that causes the optically-sub-diffractive structure to not interact diffractively with visible light.

In some implementations, imprinting the optically-diffractive structure and the optically-sub-diffractive structure is performed in a roll-to-roll, roll-to-plate, plate-to-roll, or plate-to-plate process.

In some implementations, the optically-sub-diffractive structure includes a one-dimensional grating, a two-dimensional nanostructure array, or a three-dimensional nanostructure array.

Some aspects of this disclosure describe an optical device that includes a waveguide; an imprinted grating, the grating arranged to direct light into the waveguide or out of the waveguide; and an imprinted sub-diffractive structure arranged adjacent to the grating. For example, the imprinted grating can be the optically-diffractive structure in any of the foregoing methods or any of the methods and structures discussed herein, and the imprinted sub-diffractive structure can be the optically-sub-diffractive structure in any of the foregoing methods or any of the methods and structures discussed herein.

Some aspects of this disclosure describe a display system that includes a waveguide, a waveguide; a light-coupling element including an imprinted grating; and an imprinted sub-diffractive structure arranged adjacent to the grating. For example, the imprinted grating in the light-coupling element can be the optically-diffractive structure in any of the foregoing methods or any of the methods and structures discussed herein, and the imprinted sub-diffractive structure can be the optically-sub-diffractive structure in any of the foregoing methods or any of the methods and structures discussed herein.

Some aspects of this disclosure describe an imprinting template. The imprinting template includes a first set of surface relief structures configured to imprint an optically-diffractive structure in a formable material, and a second set of surface relief structures configured to imprint an optically-sub-diffractive structure in the formable material. The second set of surface relief structures are adjacent to the first set of surface relief structures. For example, the sets of surface relief structures can be configured to imprint any of the adjacent active structures and non-active structures discussed herein. For example, the imprinting template can be used to perform any of the foregoing methods or any of the imprinting methods discussed herein.

The details of one or more embodiments are set forth in the accompanying drawings and the description below. Other aspects, features and advantages will be apparent from the description and drawings, and from the claims.

### BRIEF DESCRIPTION OF THE DRAWINGS

FIG. 1 illustrates a user's view of augmented reality (AR) through an AR device.

FIG. 2 illustrates a conventional display system for simulating three-dimensional imagery for a user.

FIGS. 3A-3C illustrate relationships between radius of curvature and focal radius.

FIG. 4A illustrates a representation of the accommodation-vergence response of the human visual system.

FIG. 4B illustrates examples of different accommodative states and vergence states of a pair of eyes of the user.

FIG. 4C illustrates an example of a representation of a top-down view of a user viewing content via a display system.

FIG. 4D illustrates another example of a representation of a top-down view of a user viewing content via a display system.

FIG. 5 illustrates aspects of an approach for simulating three-dimensional imagery by modifying wavefront divergence.

FIG. 6 illustrates an example of a waveguide stack for outputting image information to a user.

FIG. 7 illustrates an example of exit beams outputted by awaveguide.

FIG. 8 illustrates an example of a stacked waveguide assembly in which each depth plane includes images formed using multiple different component colors.

FIG. 9A illustrates a cross-sectional side view of an example of a set of stacked waveguides that each includes an in-coupling optical element.

FIG. 9B illustrates a perspective view of an example of the plurality of stacked waveguides of FIG. 9A.

FIG. 9C illustrates a top-down plan view of an example of the plurality of stacked waveguides of FIGS. 9A and 9B.

FIG. 9D illustrates an example of a wearable display system.

FIG. 10 illustrates a side view of an example of a projector assembly.

FIG. 11A illustrates a side view of an example of an augmented reality display system.

FIG. 11B illustrates a top view of the augmented reality display system of FIG. 11A.

FIG. 11C illustrates a side view of the augmented reality display system of FIG. 11A.

FIG. 12A illustrates a side view of an augmented reality display system.

FIG. 12B illustrates a side view of the augmented reality display system of FIG. 12A.

FIG. 12C illustrates a top view of the augmented reality display system of FIG. 12B.

FIG. 13 illustrates an example of an imprinting process.

FIG. 14 illustrates examples of imprinting defects.

FIG. 15 illustrates example of imprinting defects.

FIG. 16 illustrates examples of imprinted structures including active regions and non-active regions.

FIG. 17 illustrates examples of imprinted structures including active regions and non-active regions.

FIG. 18 illustrates an example of imprinted structures including a non-active region with multiple zones.

FIG. 19 illustrates an example of a process for imprinting optical structures.

FIG. 20 illustrates an example of a template and imprinted pattern.

### DETAILED DESCRIPTION

### Augmented Reality and Virtual Reality Systems

AR systems may display virtual content to a user, or viewer, while still allowing the user to see the world around them. Preferably, this content is displayed on a head-mounted display, e.g., as part of eyewear, that projects image information to the user's eyes. In addition, the display may also transmit light from the surrounding environment to the user's eyes, to allow a view of that surrounding environment. As used herein, it will be appreciated that a “head-mounted” or “head mountable” display is a display that may be mounted on the head of a viewer or user.

Various AR systems disclosed herein include a virtual/augmented/mixed display, which in turn can includes one or more optical elements formed on or as part of a waveguide. The optical elements may include, e.g., an in-coupling optical element that may be employed to couple light into a waveguide, and/or an out-coupling optical element that may be employed to couple light out of the waveguide and into the user's eyes. To achieve high efficiency in in-coupling of light into and/or out-coupling of light from the waveguide, optical elements may include diffraction gratings. In some display systems, a relatively high diffraction efficiency of the optical elements may be achieved in part by including a slanted grating, which is a type of diffraction grating that can provide high diffraction efficiency for in-coupled/out-coupled light. A slanted grating refers to a grating having an array of surface-relief trenches, where sidewalls of the trenches, in a tiling direction of the array, have a substantially uniform non-normal slant angle in reference to a surface in which the trenches are formed, such as a substrate surface. A slanted diffraction grating can be fabricated by imprinting a slanted diffraction grating pattern on a device substrate, e.g., a waveguide, using a device master template.

Reference will now be made to the drawings, in which like reference numerals refer to like parts throughout. Unless indicated otherwise, the drawings are schematic not necessarily drawn to scale.

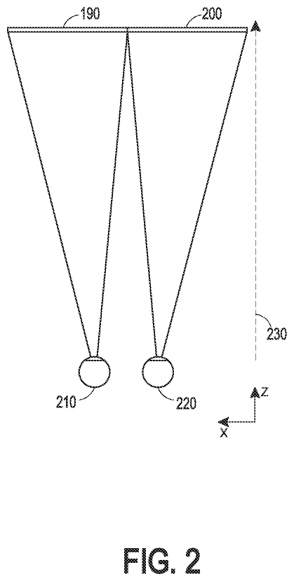

FIG. 2 illustrates a conventional display system for simulating three-dimensional imagery for a user. It will be appreciated that a user's eyes are spaced apart and that, when looking at a real object in space, each eye will have a slightly different view of the object and may form an image of the object at different locations on the retina of each eye. This may be referred to as binocular disparity and may be utilized by the human visual system to provide a perception of depth. Conventional display systems simulate binocular disparity by presenting two distinct images 190, 200 with slightly different views of the same virtual object—one for each eye 210, 220—corresponding to the views of the virtual object that would be seen by each eye were the virtual object a real object at a desired depth. These images provide binocular cues that the user's visual system may interpret to derive a perception of depth.

With continued reference to FIG. 2, the images 190, 200 are spaced from the eyes 210, 220 by a distance 230 on a z-axis. The z-axis is parallel to the optical axis of the viewer with their eyes fixated on an object at optical infinity directly ahead of the viewer. The images 190, 200 are flat and at a fixed distance from the eyes 210, 220. Based on the slightly different views of a virtual object in the images presented to the eyes 210, 220, respectively, the eyes may naturally rotate such that an image of the object falls on corresponding points on the retinas of each of the eyes, to maintain single binocular vision. This rotation may cause the lines of sight of each of the eyes 210, 220 to converge onto a point in space at which the virtual object is perceived to be present. As a result, providing three-dimensional imagery conventionally involves providing binocular cues that may manipulate the vergence of the user's eyes 210, 220, and that the human visual system interprets to provide a perception of depth.

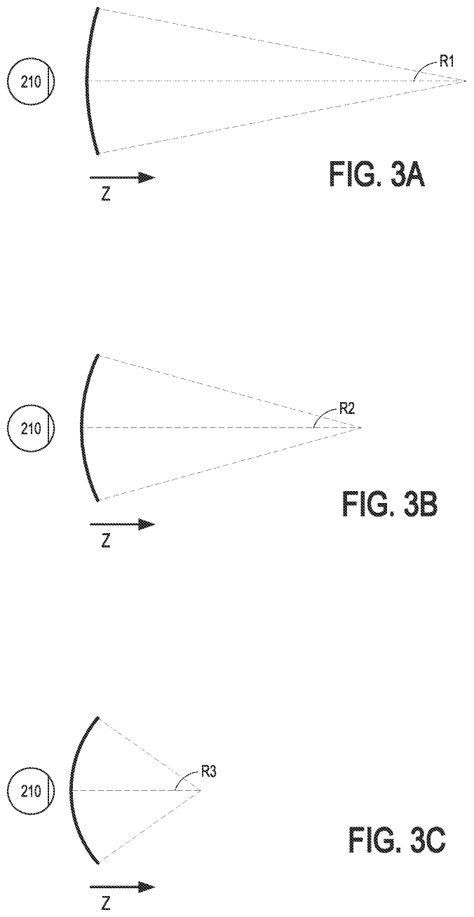

Generating a realistic and comfortable perception of depth is challenging, however. It will be appreciated that light from objects at different distances from the eyes have wavefronts with different amounts of divergence. FIGS. 3A-3C illustrate relationships between distance and the divergence of light rays. The distance between the object and the eye 210 is represented by, in order of decreasing distance, R1, R2, and R3. As shown in FIGS. 3A-3C, the light rays become more divergent as distance to the object decreases. Conversely, as distance increases, the light rays become more collimated. Stated another way, it may be said that the light field produced by a point (the object or a part of the object) has a spherical wavefront curvature, which is a function of how far away the point is from the eye of the user. The curvature increases with decreasing distance between the object and the eye 210. While only a single eye 210 is illustrated for clarity of illustration in FIGS. 3A-3C and other figures herein, the discussions regarding eye 210 may be applied to both eyes 210 and 220 of a viewer.

With continued reference to FIGS. 3A-3C, light from an object that the viewer's eyes are fixated on may have different degrees of wavefront divergence. Due to the different amounts of wavefront divergence, the light may be focused differently by the lens of the eye, which in turn may require the lens to assume different shapes to form a focused image on the retina of the eye. Where a focused image is not formed on the retina, the resulting retinal blur acts as a cue to accommodation that causes a change in the shape of the lens of the eye until a focused image is formed on the retina. For example, the cue to accommodation may trigger the ciliary muscles surrounding the lens of the eye to relax or contract, thereby modulating the force applied to the suspensory ligaments holding the lens, thus causing the shape of the lens of the eye to change until retinal blur of an object of fixation is eliminated or minimized, thereby forming a focused image of the object offixation on the retina (e.g., fovea) of the eye. The process by which the lens of the eye changes shape may be referred to as accommodation, and the shape of the lens of the eye required to form a focused image of the object of fixation on the retina (e.g., fovea) of the eye may be referred to as an accommodative state.

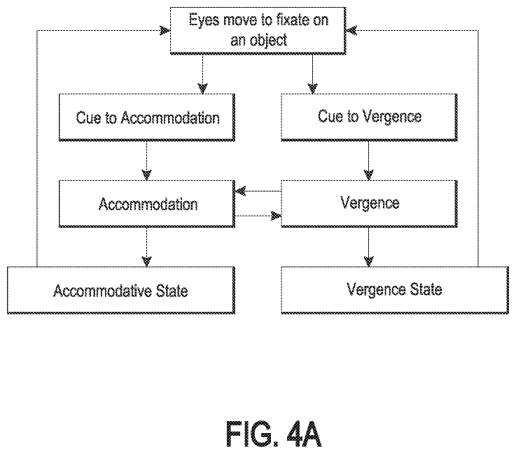

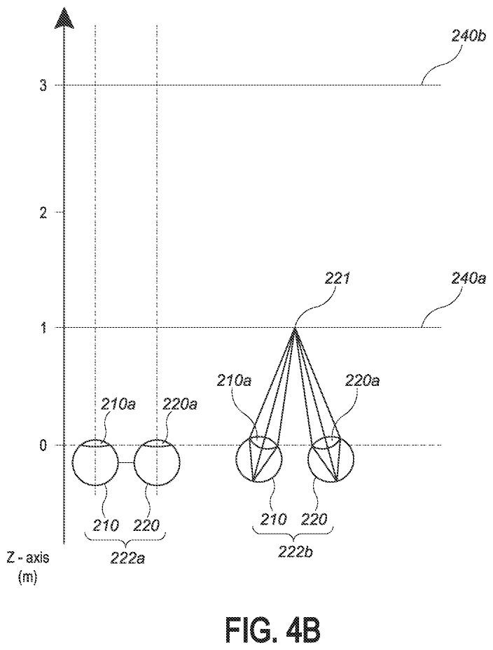

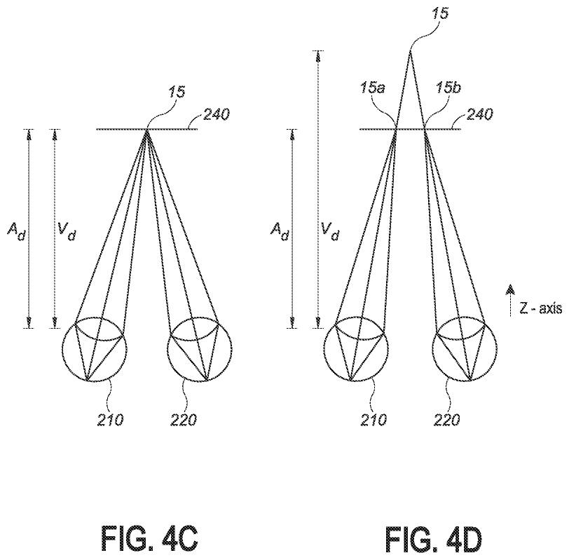

With reference now to FIG. 4A, a representation of the accommodation-vergence response of the human visual system is illustrated. The movement of the eyes to fixate on an object causes the eyes to receive light from the object, with the light forming an image on each of the retinas of the eyes. The presence of retinal blur in the image formed on the retina may provide a cue to accommodation, and the relative locations of the image on the retinas may provide a cue to vergence. The cue to accommodation causes accommodation to occur, resulting in the lenses of the eyes each assuming a particular accommodative state that forms a focused image of the object on the retina (e.g., fovea) of the eye. On the other hand, the cue to vergence causes vergence movements (rotation of the eyes) to occur such that the images formed on each retina of each eye are at corresponding retinal points that maintain single binocular vision. In these positions, the eyes may be said to have assumed a particular vergence state. With continued reference to FIG. 4A, accommodation may be understood to be the process by which the eye achieves a particular accommodative state, and vergence may be understood to be the process by which the eye achieves a particular vergence state. As indicated in FIG. 4A, the accommodative and vergence states of the eyes may change if the user fixates on another object. For example, the accommodated state may change if the user fixates on a new object at a different depth on the z-axis.

Without being limited by theory, it is believed that viewers of an object may perceive the object as being “three-dimensional” due to a combination of vergence and accommodation. As noted above, vergence movements (e.g., rotation of the eyes so that the pupils move toward or away from each other to converge the lines of sight of the eyes to fixate upon an object) of the two eyes relative to each other are closely associated with accommodation of the lenses of the eyes. Under normal conditions, changing the shapes of the lenses of the eyes to change focus from one object to another object at a different distance will automatically cause a matching change in vergence to the same distance, under a relationship known as the “accommodation-vergence reflex.” Likewise, a change in vergence will trigger a matching change in lens shape under normal conditions.

With reference now to FIG. 4B, examples of different accommodative and vergence states of the eyes are illustrated. The pair of eyes 222a is fixated on an object at optical infinity, while the pair eyes 222b are fixated on an object 221 at less than optical infinity. Notably, the vergence states of each pair of eyes is different, with the pair of eyes 222a directed straight ahead, while the pair of eyes 222 converge on the object 221. The accommodative states of the eyes forming each pair of eyes 222a and 222b are also different, as represented by the different shapes of the lenses 210a, 220a.

Undesirably, many users of conventional “3-D” display systems find such conventional systems to be uncomfortable or may not perceive a sense of depth at all due to a mismatch between accommodative and vergence states in these displays. As noted above, many stereoscopic or “3-D” display systems display a scene by providing slightly different images to each eye. Such systems are uncomfortable for many viewers, since they, among other things, simply provide different presentations of a scene and cause changes in the vergence states of the eyes, but without a corresponding change in the accommodative states of those eyes. Rather, the images are shown by a display at a fixed distance from the eyes, such that the eyes view all the image information at a single accommodative state. Such an arrangement works against the “accommodation-vergence reflex” by causing changes in the vergence state without a matching change in the accommodative state. This mismatch is believed to cause viewer discomfort. Display systems that provide a better match between accommodation and vergence may form more realistic and comfortable simulations of three-dimensional imagery.

Without being limited by theory, it is believed that the human eye typically may interpret a finite number of depth planes to provide depth perception.

Consequently, a highly believable simulation of perceived depth may be achieved by providing, to the eye, different presentations of an image corresponding to each of these limited numbers of depth planes. In some embodiments, the different presentations may provide both cues to vergence and matching cues to accommodation, thereby providing physiologically correct accommodation-vergence matching.

With continued reference to FIG. 4B, two depth planes 240, corresponding to different distances in space from the eyes 210, 220, are illustrated. For a given depth plane 240, vergence cues may be provided by the displaying of images of appropriately different perspectives for each eye 210, 220. In addition, for a given depth plane 240, light forming the images provided to each eye 210, 220 may have a wavefront divergence corresponding to a light field produced by a point at the distance of that depth plane 240.

In the illustrated embodiment, the distance, along the z-axis, of the depth plane 240 containing the point 221 is 1 m. As used herein, distances or depths along the z-axis may be measured with a zero-point located at the exit pupils of the user's eyes. Thus, a depth plane 240 located at a depth of 1 m corresponds to a distance of 1 m away from the exit pupils of the user's eyes, on the optical axis of those eyes with the eyes directed towards optical infinity. As an approximation, the depth or distance along the z-axis may be measured from the display in front of the user's eyes (e.g., from the surface of a waveguide), plus a value for the distance between the device and the exit pupils of the user's eyes. That value may be called the eye relief and corresponds to the distance between the exit pupil of the user's eye and the display worn by the user in front of the eye. In practice, the value for the eye relief may be a normalized value used generally for all viewers. For example, the eye relief may be assumed to be 20 mm and a depth plane that is at a depth of 1 m may be at a distance of 980 mm in front of the display.

With reference now to FIGS. 4C and 4D, examples of matched accommodation-vergence distances and mismatched accommodation-vergence distances are illustrated, respectively. As illustrated in FIG. 4C, the display system may provide images of a virtual object to each eye 210, 220. The images may cause the eyes 210, 220 to assume a vergence state in which the eyes converge on a point 15 on a depth plane 240. In addition, the images may be formed by a light having a wavefront curvature corresponding to real objects at that depth plane 240. As a result, the eyes 210, 220 assume an accommodative state in which the images are in focus on the retinas of those eyes. Thus, the user may perceive the virtual object as being at the point 15 on the depth plane 240.

It will be appreciated that each of the accommodative and vergence states of the eyes 210, 220 are associated with a particular distance on the z-axis. For example, an object at a particular distance from the eyes 210, 220 causes those eyes to assume particular accommodative states based upon the distances of the object. The distance associated with a particular accommodative state may be referred to as the accommodation distance, Ad. Similarly, there are particular vergence distances, V_{d}, associated with the eyes in particular vergence states, or positions relative to one another. Where the accommodation distance and the vergence distance match, the relationship between accommodation and vergence may be said to be physiologically correct. This is considered to be the most comfortable scenario for a viewer.

In stereoscopic displays, however, the accommodation distance and the vergence distance may not always match. For example, as illustrated in FIG. 4D, images displayed to the eyes 210, 220 may be displayed with wavefront divergence corresponding to depth plane 240, and the eyes 210, 220 may assume a particular accommodative state in which the points 15a, 15b on that depth plane are in focus. However, the images displayed to the eyes 210, 220 may provide cues for vergence that cause the eyes 210, 220 to converge on a point 15 that is not located on the depth plane 240. As a result, the accommodation distance corresponds to the distance from the exit pupils of the eyes 210, 220 to the depth plane 240, while the vergence distance corresponds to the larger distance from the exit pupils of the eyes 210, 220 to the point 15, in some embodiments. The accommodation distance is different from the vergence distance. Consequently, there is an accommodation-vergence mismatch. Such a mismatch is considered undesirable and may cause discomfort in the user. It will be appreciated that the mismatch corresponds to distance (e.g., Va-Ad) and may be characterized using diopters.

In some embodiments, it will be appreciated that a reference point other than exit pupils of the eyes 210, 220 may be utilized for determining distance for determining accommodation-vergence mismatch, so long as the same reference point is utilized for the accommodation distance and the vergence distance. For example, the distances could be measured from the cornea to the depth plane, from the retina to the depth plane, from the eyepiece (e.g., a waveguide of the display device) to the depth plane, and so on.

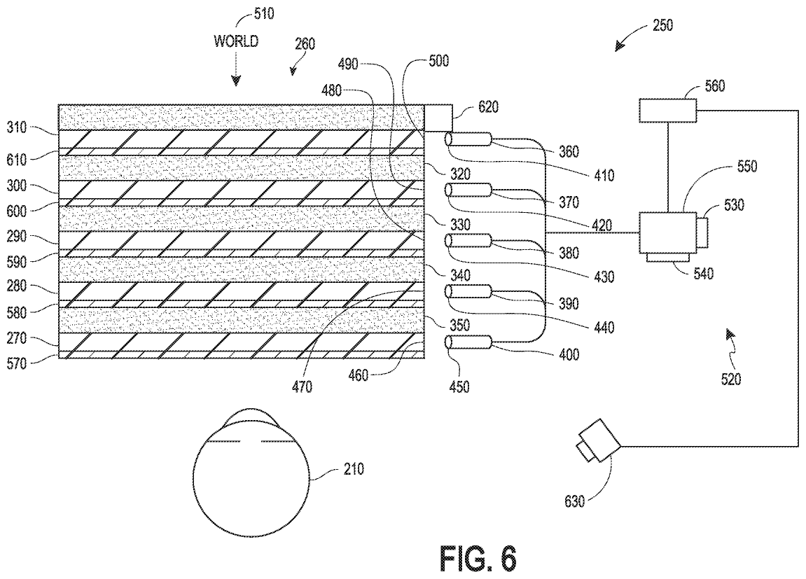

Without being limited by theory, it is believed that users may still perceive accommodation-vergence mismatches of up to about 0.25 diopter, up to about 0.33 diopter, and up to about 0.5 diopter as being physiologically correct, without the mismatch itself causing significant discomfort. In some embodiments, display systems disclosed herein (e.g., the display system 250, FIG. 6) present images to the viewer having accommodation-vergence mismatch of about 0.5 diopter or less. In some other embodiments, the accommodation-vergence mismatch of the images provided by the display system is about 0.33 diopter or less. In yet other embodiments, the accommodation-vergence mismatch of the images provided by the display system is about 0.25 diopter or less, including about 0.1 diopter or less.

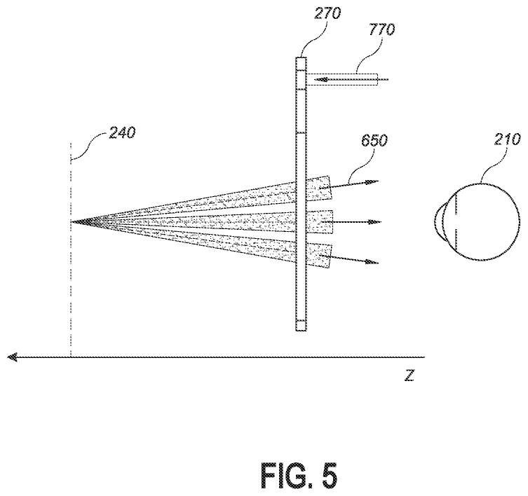

FIG. 5 illustrates aspects of an approach for simulating three-dimensional imagery by modifying wavefront divergence. The display system includes a waveguide 270 that is configured to receive light 770 that is encoded with image information, and to output that light to the user's eye 210. The waveguide 270 may output the light 650 with a defined amount of wavefront divergence corresponding to the wavefront divergence of a light field produced by a point on a desired depth plane 240. In some embodiments, the same amount of wavefront divergence is provided for all objects presented on that depth plane. In addition, it will be illustrated that the other eye of the user may be provided with image information from a similar waveguide.

In some embodiments, a single waveguide may be configured to output light with a set amount of wavefront divergence corresponding to a single or limited number of depth planes and/or the waveguide may be configured to output light of a limited range of wavelengths. Consequently, in some embodiments, a plurality or stack of waveguides may be utilized to provide different amounts of wavefront divergence for different depth planes and/or to output light of different ranges of wavelengths. As used herein, it will be appreciated at a depth plane may be planar or may follow the contours of a curved surface.

FIG. 6 illustrates an example of a waveguide stack for outputting image information to a user. A display system 250 includes a stack of waveguides, or stacked waveguide assembly, 260 that may be utilized to provide three-dimensional perception to the eye/brain using a plurality of waveguides 270, 280, 290, 300, 310. It will be appreciated that the display system 250 may be considered a light field display in some embodiments. In addition, the waveguide assembly 260 may also be referred to as an eyepiece.

In some embodiments, the display system 250 may be configured to provide substantially continuous cues to vergence and multiple discrete cues to accommodation. The cues to vergence may be provided by displaying different images to each of the eyes of the user, and the cues to accommodation may be provided by outputting the light that forms the images with selectable discrete amounts of wavefront divergence. Stated another way, the display system 250 may be configured to output light with variable levels of wavefront divergence. In some embodiments, each discrete level of wavefront divergence corresponds to a particular depth plane and may be provided by a particular one of the waveguides 270, 280, 290, 300, 310.

With continued reference to FIG. 6, the waveguide assembly 260 may also include a plurality of features 320, 330, 340, 350 between the waveguides. In some embodiments, the features 320, 330, 340, 350 may be one or more lenses. The waveguides 270, 280, 290, 300, 310 and/or the plurality of lenses 320, 330, 340, 350 may be configured to send image information to the eye with various levels of wavefront curvature or light ray divergence. Each waveguide level may be associated with a particular depth plane and may be configured to output image information corresponding to that depth plane. Image injection devices 360, 370, 380, 390, 400 may function as a source of light for the waveguides and may be utilized to inject image information into the waveguides 270, 280, 290, 300, 310, each of which may be configured, as described herein, to distribute incoming light across each respective waveguide, for output toward the eye 210. Light exits an output surface 410, 420, 430, 440, 450 of the image injection devices 360, 370, 380, 390, 400 and is injected into a corresponding input surface 460, 470, 480, 490, 500 of the waveguides 270, 280, 290, 300, 310. In some embodiments, each of the input surfaces 460, 470, 480, 490, 500 may be an edge of a corresponding waveguide, or may be part of a major surface of the corresponding waveguide (that is, one of the waveguide surfaces directly facing the world 510 or the viewer's eye 210). In some embodiments, a single beam of light (e.g. a collimated beam) may be injected into each waveguide to output an entire field of cloned collimated beams that are directed toward the eye 210 at particular angles (and amounts of divergence) corresponding to the depth plane associated with a particular waveguide. In some embodiments, a single one of the image injection devices 360, 370, 380, 390, 400 may be associated with and inject light into a plurality (e.g., three) of the waveguides 270, 280, 290, 300, 310.

In some embodiments, the image injection devices 360, 370, 380, 390, 400 are discrete displays that each produce image information for injection into a corresponding waveguide 270, 280, 290, 300, 310, respectively. In some other embodiments, the image injection devices 360, 370, 380, 390, 400 are the output ends of a single multiplexed display which may, e.g., pipe image information via one or more optical conduits (such as fiber optic cables) to each of the image injection devices 360, 370, 380, 390, 400. It will be appreciated that the image information provided by the image injection devices 360, 370, 380, 390, 400 may include light of different wavelengths, or colors (e.g., different component colors, as discussed herein).

In some embodiments, the light injected into the waveguides 270, 280, 290, 300, 310 is provided by a light projector system 520, which includes a light module 530, which may include a light emitter, such as a light emitting diode (LED). The light from the light module 530 may be directed to and modified by a light modulator 540, e.g., a spatial light modulator, via a beam splitter 550. The light modulator 540 may be configured to change the perceived intensity of the light injected into the waveguides 270, 280, 290, 300, 310 to encode the light with image information. Examples of spatial light modulators include liquid crystal displays (LCD) including a liquid crystal on silicon (LCOS) displays. It will be appreciated that the image injection devices 360, 370, 380, 390, 400 are illustrated schematically and, in some embodiments, these image injection devices may represent different light paths and locations in a common projection system configured to output light into associated ones of the waveguides 270, 280, 290, 300, 310. In some embodiments, the waveguides of the waveguide assembly 260 may function as ideal lens while relaying light injected into the waveguides out to the user's eyes. In this conception, the object may be the spatial light modulator 540 and the image may be the image on the depth plane.

In some embodiments, the display system 250 may be a scanning fiber display including one or more scanning fibers configured to project light in various patterns (e.g., raster scan, spiral scan, Lissajous patterns, etc.) into one or more waveguides 270, 280, 290, 300, 310 and ultimately to the eye 210 of the viewer. In some embodiments, the illustrated image injection devices 360, 370, 380, 390, 400 may schematically represent a single scanning fiber or a bundle of scanning fibers configured to inject light into one or a plurality of the waveguides 270, 280, 290, 300, 310. In some other embodiments, the illustrated image injection devices 360, 370, 380, 390, 400 may schematically represent a plurality of scanning fibers or a plurality of bundles of scanning fibers, each of which are configured to inject light into an associated one of the waveguides 270, 280, 290, 300, 310. It will be appreciated that one or more optical fibers may be configured to transmit light from the light module 530 to the one or more waveguides 270, 280, 290, 300, 310. It will be appreciated that one or more intervening optical structures may be provided between the scanning fiber, or fibers, and the one or more waveguides 270, 280, 290, 300, 310 to, e.g., redirect light exiting the scanning fiber into the one or more waveguides 270, 280, 290, 300, 310.

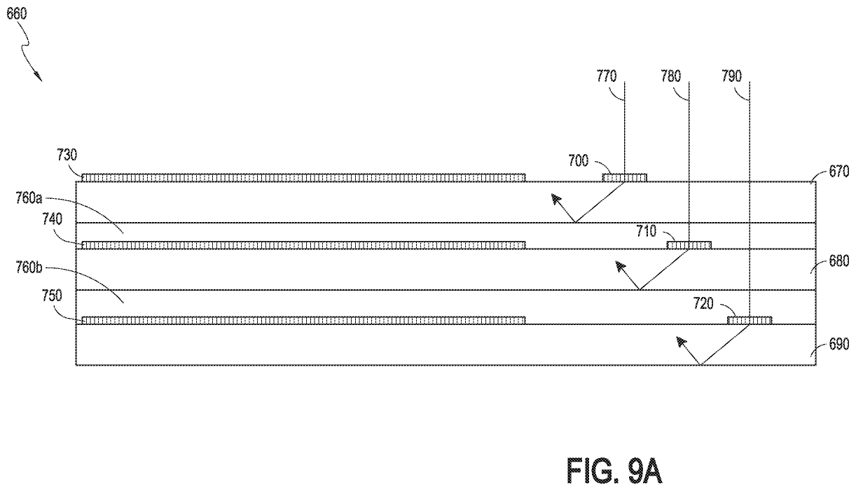

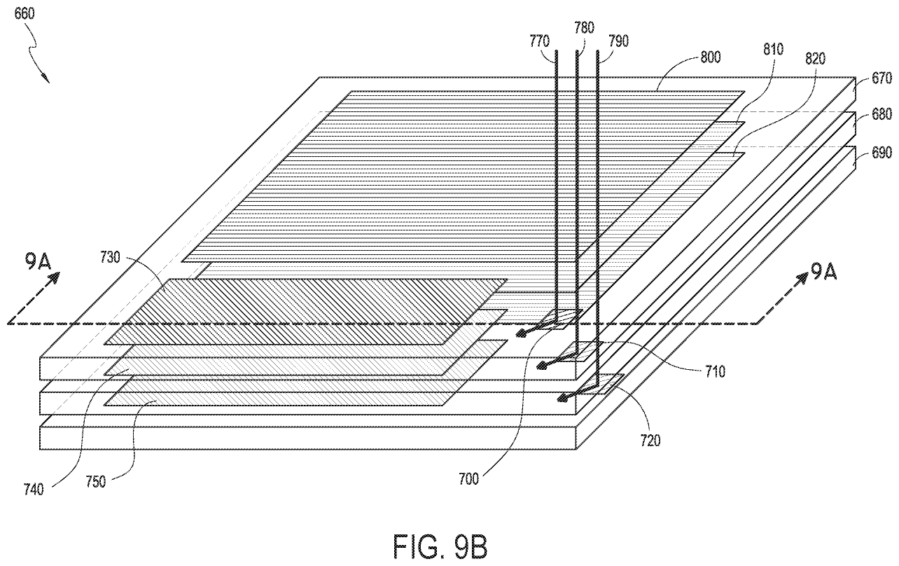

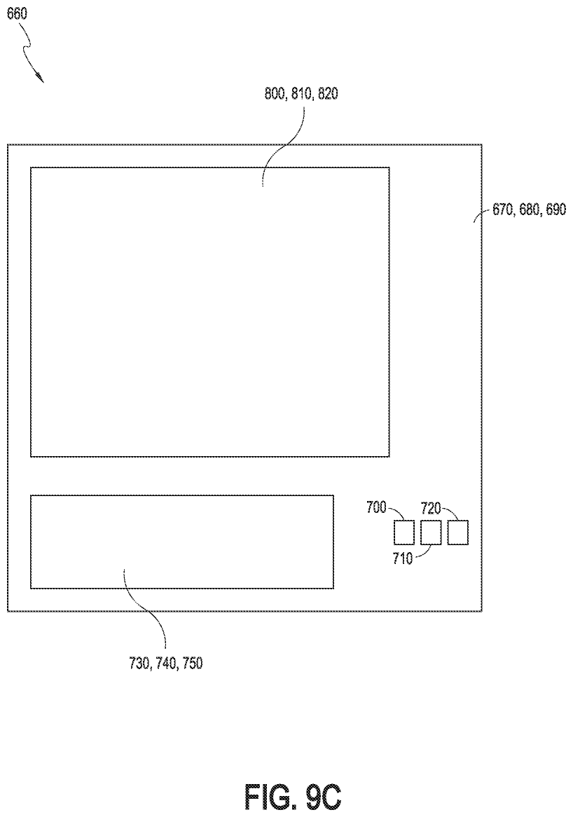

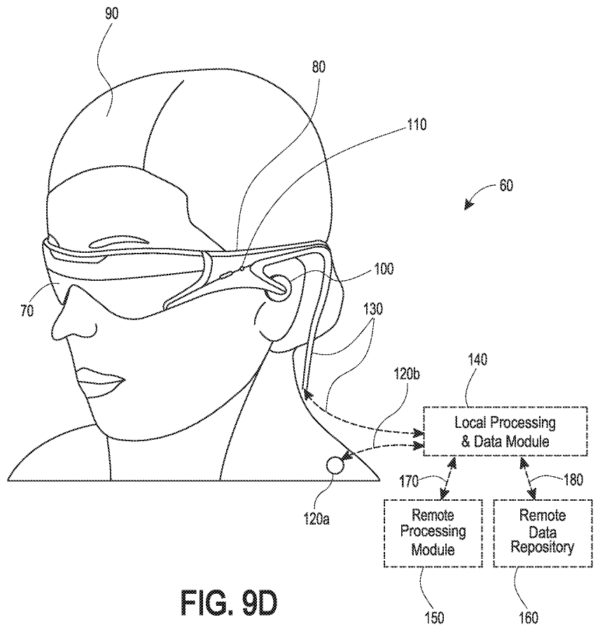

A controller 560 controls the operation of one or more of the stacked waveguide assembly 260, including operation of the image injection devices 360, 370, 380, 390, 400, the light source 530, and the light modulator 540. In some embodiments, the controller 560 is part of the local data processing module 140. The controller 560 includes programming (e.g., instructions in a non-transitory medium) that regulates the timing and provision of image information to the waveguides 270, 280, 290, 300, 310 according to, e.g., any of the various schemes disclosed herein. In some embodiments, the controller may be a single integral device, or a distributed system connected by wired or wireless communication channels. The controller 560 may be part of the processing modules 140 or 150 (FIG. 9D) in some embodiments.

With continued reference to FIG. 6, the waveguides 270, 280, 290, 300, 310 may be configured to propagate light within each respective waveguide by total internal reflection (TIR). The waveguides 270, 280, 290, 300, 310 may each be planar or have another shape (e.g., curved), with major top and bottom surfaces and edges extending between those major top and bottom surfaces. In the illustrated configuration, the waveguides 270, 280, 290, 300, 310 may each include out-coupling optical elements 570, 580, 590, 600, 610 that are configured to extract light out of a waveguide by redirecting the light, propagating within each respective waveguide, out of the waveguide to output image information to the eye 210. Extracted light may also be referred to as out-coupled light and the out-coupling optical elements light may also be referred to light extracting optical elements. An extracted beam of light may be outputted by the waveguide at locations at which the light propagating in the waveguide strikes a light extracting optical element. The out-coupling optical elements 570, 580, 590, 600, 610 may, for example, be gratings (e.g., gratings in an active/diffractive region having an adjacent non-active/sub-diffractive region), including diffractive optical features, as discussed further herein. While illustrated disposed at the bottom major surfaces of the waveguides 270, 280, 290, 300, 310, for ease of description and drawing clarity, in some embodiments, the out-coupling optical elements 570, 580, 590, 600, 610 may be disposed at the top and/or bottom major surfaces, and/or may be disposed directly in the volume of the waveguides 270, 280, 290, 300, 310, as discussed further herein. In some embodiments, the out-coupling optical elements 570, 580, 590, 600, 610 may be formed in a layer of material that is attached to a transparent substrate to form the waveguides 270, 280, 290, 300, 310. In some other embodiments, the waveguides 270, 280, 290, 300, 310 may be a monolithic piece of material and the out-coupling optical elements 570, 580, 590, 600, 610 may be formed on a surface and/or in the interior of that piece of material.

With continued reference to FIG. 6, as discussed herein, each waveguide 270, 280, 290, 300, 310 is configured to output light to form an image corresponding to a particular depth plane. For example, the waveguide 270 nearest the eye may be configured to deliver collimated light (which was injected into such waveguide 270), to the eye 210. The collimated light may be representative of the optical infinity focal plane. The next waveguide up 280 may be configured to send out collimated light which passes through the first lens 350 (e.g., a negative lens) before it may reach the eye 210; such first lens 350 may be configured to create a slight convex wavefront curvature so that the eye/brain interprets light coming from that next waveguide up 280 as coming from a first focal plane closer inward toward the eye 210 from optical infinity. Similarly, the third up waveguide 290 passes its output light through both the first 350 and second 340 lenses before reaching the eye 210; the combined optical power of the first 350 and second 340 lenses may be configured to create another incremental amount of wavefront curvature so that the eye/brain interprets light coming from the third waveguide 290 as coming from a second focal plane that is even closer inward toward the person from optical infinity than was light from the next waveguide up 280.

The other waveguide layers 300, 310 and lenses 330, 320 are similarly configured, with the highest waveguide 310 in the stack sending its output through all of the lenses between it and the eye for an aggregate focal power representative of the closest focal plane to the person. To compensate for the stack of lenses 320, 330, 340, 350 when viewing/interpreting light coming from the world 510 on the other side of the stacked waveguide assembly 260, a compensating lens layer 620 may be disposed at the top of the stack to compensate for the aggregate power of the lens stack 320, 330, 340, 350 below. Such a configuration provides as many perceived focal planes as there are available waveguide/lens pairings. Both the out-coupling optical elements of the waveguides and the focusing aspects of the lenses may be static (i.e., not dynamic or electro-active). In some alternative embodiments, either or both may be dynamic using electro-active features.

In some embodiments, two or more of the waveguides 270, 280, 290, 300, 310 may have the same associated depth plane. For example, multiple waveguides 270, 280, 290, 300, 310 may be configured to output images set to the same depth plane, or multiple subsets of the waveguides 270, 280, 290, 300, 310 may be configured to output images set to the same plurality of depth planes, with one set for each depth plane. This may provide advantages for forming a tiled image to provide an expanded field of view at those depth planes.

With continued reference to FIG. 6, the out-coupling optical elements 570, 580, 590, 600, 610 may be configured to both redirect light out of their respective waveguides and to output this light with the appropriate amount of divergence or collimation for a particular depth plane associated with the waveguide. As a result, waveguides having different associated depth planes may have different configurations of out-coupling optical elements 570, 580, 590, 600, 610, which output light with a different amount of divergence depending on the associated depth plane. In some embodiments, the light extracting optical elements 570, 580, 590, 600, 610 may be volumetric or surface features, which may be configured to output light at specific angles. For example, the light extracting optical elements 570, 580, 590, 600, 610 may be volume holograms, surface holograms, and/or diffraction gratings. In some embodiments, the features 320, 330, 340, 350 may not be lenses; rather, they may simply be spacers (e.g., cladding layers and/or structures for forming air gaps).

In some embodiments, the out-coupling optical elements 570, 580, 590, 600, 610 are diffractive features that form a diffraction pattern, or “diffractive optical element” (also referred to herein as a “DOE”). Preferably, the DOE's have a sufficiently low diffraction efficiency so that only a portion of the light of the beam is deflected away toward the eye 210 with each intersection of the DOE, while the rest continues to move through a waveguide via TIR. The light carrying the image information is thus divided into a number of related exit beams that exit the waveguide at a multiplicity of locations and the result is a fairly uniform pattern of exit emission toward the eye 210 for this particular collimated beam bouncing around within a waveguide.

In some embodiments, one or more DOEs may be switchable between “on” states in which they actively diffract, and “off” states in which they do not significantly diffract. For instance, a switchable DOE may include a layer of polymer dispersed liquid crystal, in which microdroplets include a diffraction pattern in a host medium, and the refractive index of the microdroplets may be switched to substantially match the refractive index of the host material (in which case the pattern does not appreciably diffract incident light) or the microdroplet may be switched to an index that does not match that of the host medium (in which case the pattern actively diffracts incident light).

In some embodiments, a camera assembly 630 (e.g., a digital camera, including visible light and infrared light cameras) may be provided to capture images of the eye 210 and/or tissue around the eye 210 to, e.g., detect user inputs and/or to monitor the physiological state of the user. As used herein, a camera may be any image capture device. In some embodiments, the camera assembly 630 may include an image capture device and a light source to project light (e.g., infrared light) to the eye, which may then be reflected by the eye and detected by the image capture device. In some embodiments, the camera assembly 630 may be attached to the frame 80 (FIG. 9D) and may be in electrical communication with the processing modules 140 and/or 150, which may process image information from the camera assembly 630. In some embodiments, one camera assembly 630 may be utilized for each eye, to separately monitor each eye.

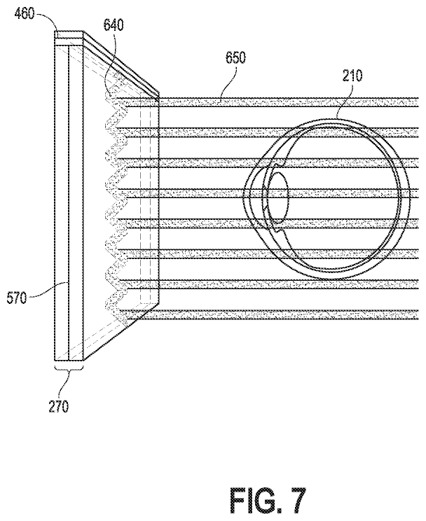

With reference now to FIG. 7, an example of exit beams outputted by a waveguide is shown. One waveguide is illustrated, but it will be appreciated that other waveguides in the waveguide assembly 260 (FIG. 6) may function similarly, where the waveguide assembly 260 includes multiple waveguides. Light 640 is injected into the waveguide 270 at the input surface 460 of the waveguide 270 and propagates within the waveguide 270 by TIR. At points where the light 640 impinges on the DOE 570, a portion of the light exits the waveguide as exit beams 650. The exit beams 650 are illustrated as substantially parallel but, as discussed herein, they may also be redirected to propagate to the eye 210 at an angle (e.g., forming divergent exit beams), depending on the depth plane associated with the waveguide 270. It will be appreciated that substantially parallel exit beams may be indicative of a waveguide with out-coupling optical elements that out-couple light to form images that appear to be set on a depth plane at a large distance (e.g., optical infinity) from the eye 210. Other waveguides or other sets of out-coupling optical elements may output an exit beam pattern that is more divergent, which would require the eye 210 to accommodate to a closer distance to bring it into focus on the retina and would be interpreted by the brain as light from a distance closer to the eye 210 than optical infinity.

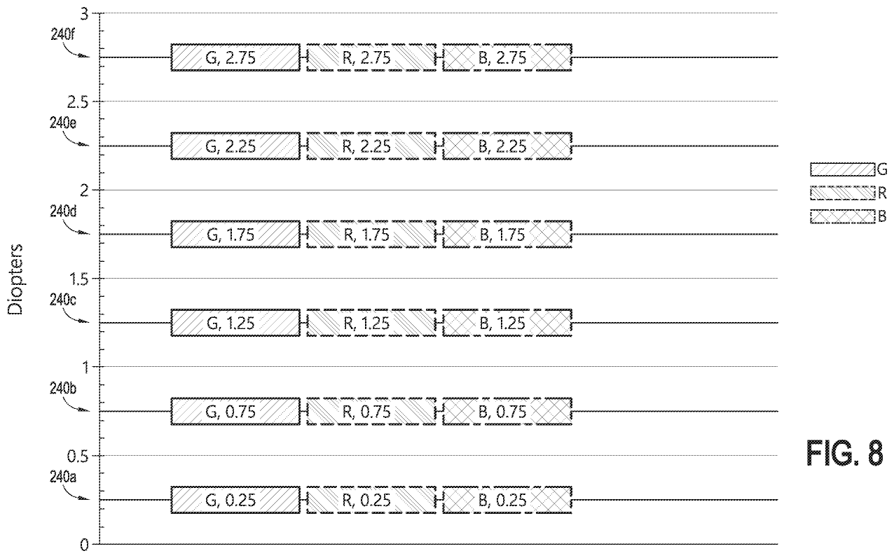

In some embodiments, a full color image may be formed at each depth plane by overlaying images in each of the component colors, e.g., three or more component colors. FIG. 8 illustrates an example of a stacked waveguide assembly in which each depth plane includes images formed using multiple different component colors. The illustrated embodiment shows depth planes 240a-240f, although more or fewer depths are also contemplated. Each depth plane may have three or more component color images associated with it, including: a first image of a first color, G; a second image of a second color, R; and a third image of a third color, B. Different depth planes are indicated in the figure by different numbers for diopters (dpt) following the letters G, R, and B. Just as examples, the numbers following each of these letters indicate diopters (1/m), or inverse distance of the depth plane from a viewer, and each box in the figures represents an individual component color image. In some embodiments, to account for differences in the eye's focusing of light of different wavelengths, the exact placement of the depth planes for different component colors may vary. For example, different component color images for a given depth plane may be placed on depth planes corresponding to different distances from the user. Such an arrangement may increase visual acuity and user comfort and/or may decrease chromatic aberrations.

In some embodiments, light of each component color may be outputted by a single dedicated waveguide and, consequently, each depth plane may have multiple waveguides associated with it. In such embodiments, each box in the figures including the letters G, R, or B may be understood to represent an individual waveguide, and three waveguides may be provided per depth plane where three component color images are provided per depth plane. While the waveguides associated with each depth plane are shown adjacent to one another in this drawing for ease of description, it will be appreciated that, in a physical device, the waveguides may all be arranged in a stack with one waveguide per level. In some other embodiments, multiple component colors may be outputted by the same waveguide, such that, e.g., only a single waveguide may be provided per depth plane.

With continued reference to FIG. 8, in some embodiments, G is the color green, R is the color red, and B is the color blue. In some other embodiments, other colors associated with other wavelengths of light, including magenta and cyan, may be used in addition to or may replace one or more of red, green, or blue.

It will be appreciated that references to a given color of light throughout this disclosure will be understood to encompass light of one or more wavelengths within a range of wavelengths of light that are perceived by a viewer as being of that given color. For example, red light may include light of one or more wavelengths in the range of about 620-780 nm, green light may include light of one or more wavelengths in the range of about 492-577 nm, and blue light may include light of one or more wavelengths in the range of about 435-493 nm.

In some embodiments, the light source 530 (FIG. 6) may be configured to emit light of one or more wavelengths outside the visual perception range of the viewer, for example, infrared and/or ultraviolet wavelengths. In addition, the in-coupling, out-coupling, and other light redirecting structures of the waveguides of the display system 250 may be configured to direct and emit this light out of the display towards the user's eye 210, e.g., for imaging and/or user stimulation applications.

With reference now to FIG. 9A, in some embodiments, light impinging on a waveguide may need to be redirected to in-couple that light into the waveguide. An in-coupling optical element may be used to redirect and in-couple the light into its corresponding waveguide. FIG. 9A illustrates a cross-sectional side view of an example of a plurality or set 660 of stacked waveguides that each includes an in-coupling optical element. The waveguides may each be configured to output light of one or more different wavelengths, or one or more different ranges of wavelengths. It will be appreciated that the stack 660 may correspond to the stacked waveguide assembly 260 (FIG. 6) and the illustrated waveguides of the stack 660 may correspond to part of the plurality of waveguides 270, 280, 290, 300, 310, except that light from one or more of the image injection devices 360, 370, 380, 390, 400 is injected into the waveguides from a position that requires light to be redirected for in-coupling.

The illustrated set 660 of stacked waveguides includes waveguides 670, 680, and 690. Each waveguide includes an associated in-coupling optical element (which may also be referred to as a light input area on the waveguide), with, e.g., in-coupling optical element 700 disposed on a major surface (e.g., an upper major surface) of waveguide 670, in-coupling optical element 710 disposed on a major surface (e.g., an upper major surface) of waveguide 680, and in-coupling optical element 720 disposed on a major surface (e.g., an upper major surface) of waveguide 690. In some embodiments, one or more of the in-coupling optical elements 700, 710, 720 may be disposed on the bottom major surface of the respective waveguide 670, 680, 690 (particularly where the one or more in-coupling optical elements are reflective, deflecting optical elements). As illustrated, the in-coupling optical elements 700, 710, 720 may be disposed on the upper major surface of their respective waveguide 670, 680, 690 (or the top of the next lower waveguide), particularly where those in-coupling optical elements are transmissive, deflecting optical elements. In some embodiments, the in-coupling optical elements 700, 710, 720 may be disposed in the body of the respective waveguide 670, 680, 690. In some embodiments, as discussed herein, the in-coupling optical elements 700, 710, 720 are wavelength selective, such that they selectively redirect one or more wavelengths of light, while transmitting other wavelengths of light. While illustrated on one side or corner of their respective waveguide 670, 680, 690, it will be appreciated that the in-coupling optical elements 700, 710, 720 may be disposed in other areas of their respective waveguide 670, 680, 690 in some embodiments.

As illustrated, the in-coupling optical elements 700, 710, 720 may be laterally offset from one another. In some embodiments, each in-coupling optical element may be offset such that it receives light without that light passing through another in-coupling optical element. For example, each in-coupling optical element 700, 710, 720 may be configured to receive light from a different image injection device 360, 370, 380, 390, and 400 as shown in FIG. 6, and may be separated (e.g., laterally spaced apart) from other in-coupling optical elements 700, 710, 720 such that it substantially does not receive light from the other ones of the in-coupling optical elements 700, 710, 720.

Each waveguide also includes associated light distributing elements, with, e.g., light distributing elements 730 disposed on a major surface (e.g., a top major surface) of waveguide 670, light distributing elements 740 disposed on a major surface (e.g., a top major surface) of waveguide 680, and light distributing elements 750 disposed on a major surface (e.g., a top major surface) of waveguide 690. In some other embodiments, the light distributing elements 730, 740, 750, may be disposed on a bottom major surface of associated waveguides 670, 680, 690, respectively. In some other embodiments, the light distributing elements 730, 740, 750, may be disposed on both top and bottom major surface of associated waveguides 670, 680, 690, respectively; or the light distributing elements 730, 740, 750, may be disposed on different ones of the top and bottom major surfaces in different associated waveguides 670, 680, 690, respectively.

The waveguides 670, 680, 690 may be spaced apart and separated by, e.g., gas, liquid, and/or solid layers of material. For example, as illustrated, layer 760a may separate waveguides 670 and 680; and layer 760b may separate waveguides 680 and 690. In some embodiments, the layers 760a and 760b are formed of low refractive index materials (that is, materials having a lower refractive index than the material forming the immediately adjacent one of waveguides 670, 680, 690). Preferably, the refractive index of the material forming the layers 760a, 760b is 0.05 or more, or 0.10 or less than the refractive index of the material forming the waveguides 670, 680, 690. Advantageously, the lower refractive index layers 760a, 760b may function as cladding layers that facilitate total internal reflection (TIR) of light through the waveguides 670, 680, 690 (e.g., TIR between the top and bottom major surfaces of each waveguide). In some embodiments, the layers 760a, 760b are formed of air. While not illustrated, it will be appreciated that the top and bottom of the illustrated set 660 of waveguides may include immediately neighboring cladding layers.

Preferably, for ease of manufacturing and other considerations, the material forming the waveguides 670, 680, 690 are similar or the same, and the material forming the layers 760a, 760b are similar or the same. In some embodiments, the material forming the waveguides 670, 680, 690 may be different between one or more waveguides, and/or the material forming the layers 760a, 760b may be different, while still holding to the various refractive index relationships noted above.

With continued reference to FIG. 9A, light rays 770, 780, 790 are incident on the set 660 of waveguides. It will be appreciated that the light rays 770, 780, 790 may be injected into the waveguides 670, 680, 690 by one or more image injection devices 360, 370, 380, 390, 400 (FIG. 6).

In some embodiments, the light rays 770, 780, 790 have different properties, e.g., different wavelengths or different ranges of wavelengths, which may correspond to different colors. The in-coupling optical elements 700, 710, 720 each deflect the incident light such that the light propagates through a respective one of the waveguides 670, 680, 690 by TIR. In some embodiments, the incoupling optical elements 700, 710, 720 each selectively deflect one or more particular wavelengths of light, while transmitting other wavelengths to an underlying waveguide and associated incoupling optical element.

For example, in-coupling optical element 700 may be configured to deflect ray 770, which has a first wavelength or range of wavelengths, while transmitting rays 780 and 790, which have different second and third wavelengths or ranges of wavelengths, respectively. The transmitted ray 780 impinges on and is deflected by the in-coupling optical element 710, which is configured to deflect light of a second wavelength or range of wavelengths. The ray 790 is deflected by the in-coupling optical element 720, which is configured to selectively deflect light of third wavelength or range of wavelengths.

With continued reference to FIG. 9A, the deflected light rays 770, 780, 790 are deflected so that they propagate through a corresponding waveguide 670, 680, 690; that is, the in-coupling optical elements 700, 710, 720 of each waveguide deflects light into that corresponding waveguide 670, 680, 690 to in-couple light into that corresponding waveguide. The light rays 770, 780, 790 are deflected at angles that cause the light to propagate through the respective waveguide 670, 680, 690 by TIR. The light rays 770, 780, 790 propagate through the respective waveguide 670, 680, 690 by TIR until impinging on the waveguide's corresponding light distributing elements 730, 740, 750.

With reference now to FIG. 9B, a perspective view of an example of the plurality of stacked waveguides of FIG. 9A is illustrated. As noted above, the in-coupled light rays 770, 780, 790, are deflected by the in-coupling optical elements 700, 710, 720, respectively, and then propagate by TIR within the waveguides 670, 680, 690, respectively. The light rays 770, 780, 790 then impinge on the light distributing elements 730, 740, 750, respectively. The light distributing elements 730, 740, 750 deflect the light rays 770, 780, 790 so that they propagate towards the out-coupling optical elements 800, 810, 820, respectively.

In some embodiments, the light distributing elements 730, 740, 750 are orthogonal pupil expanders (OPE's). In some embodiments, the OPE's deflect or distribute light to the out-coupling optical elements 800, 810, 820 and, in some embodiments, may also increase the beam or spot size of this light as it propagates to the out-coupling optical elements. In some embodiments, the light distributing elements 730, 740, 750 may be omitted and the in-coupling optical elements 700, 710, 720 may be configured to deflect light directly to the out-coupling optical elements 800, 810, 820. For example, with reference to FIG. 9A, the light distributing elements 730, 740, 750 may be replaced with out-coupling optical elements 800, 810, 820, respectively. In some embodiments, the out-coupling optical elements 800, 810, 820 are exit pupils (EP's) or exit pupil expanders (EPE's) that direct light in a viewer's eye 210 (FIG. 7). It will be appreciated that the OPE's may be configured to increase the dimensions of the eye box in at least one axis and the EPE's may be to increase the eye box in an axis crossing, e.g., orthogonal to, the axis of the OPEs. For example, each OPE may be configured to redirect a portion of the light striking the OPE to an EPE of the same waveguide, while allowing the remaining portion of the light to continue to propagate down the waveguide. Upon impinging on the OPE again, another portion of the remaining light is redirected to the EPE, and the remaining portion of that portion continues to propagate further down the waveguide, and so on. Similarly, upon striking the EPE, a portion of the impinging light is directed out of the waveguide towards the user, and a remaining portion of that light continues to propagate through the waveguide until it strikes the EP again, at which time another portion of the impinging light is directed out of the waveguide, and so on. Consequently, a single beam of incoupled light may be “replicated” each time a portion of that light is redirected by an OPE or EPE, thereby forming a field of cloned beams of light, as shown in FIG. 6. In some embodiments, the OPE and/or EPE may be configured to modify a size of the beams of light.

Accordingly, with reference to FIGS. 9A and 9B, in some embodiments, the set 660 of waveguides includes waveguides 670, 680, 690; in-coupling optical elements 700, 710, 720; light distributing elements (e.g., OPE's) 730, 740, 750; and out-coupling optical elements (e.g., EP's) 800, 810, 820 for each component color. The waveguides 670, 680, 690 may be stacked with an air gap/cladding layer between each one. The in-coupling optical elements 700, 710, 720 redirect or deflect incident light (with different in-coupling optical elements receiving light of different wavelengths) into its waveguide. The light then propagates at an angle which will result in TIR within the respective waveguide 670, 680, 690. In the example shown, light ray 770 (e.g., blue light) is deflected by the first in-coupling optical element 700, and then continues to bounce down the waveguide, interacting with the light distributing element (e.g., OPE's) 730 and then the out-coupling optical element (e.g., EPs) 800, in a manner described earlier. The light rays 780 and 790 (e.g., green and red light, respectively) will pass through the waveguide 670, with light ray 780 impinging on and being deflected by in-coupling optical element 710. The light ray 780 then bounces down the waveguide 680 via TIR, proceeding on to its light distributing element (e.g., OPEs) 740 and then the out-coupling optical element (e.g., EP's) 810. Finally, light ray 790 (e.g., red light) passes through the waveguide 690 to impinge on the light in-coupling optical elements 720 of the waveguide 690. The light in-coupling optical elements 720 deflect the light ray 790 such that the light ray propagates to light distributing element (e.g., OPEs) 750 by TIR, and then to the out-coupling optical element (e.g., EPs) 820 by TIR. The out-coupling optical element 820 then finally out-couples the light ray 790 to the viewer, who also receives the out-coupled light from the other waveguides 670, 680.

FIG. 9C illustrates a top-down plan view of an example of the plurality of stacked waveguides of FIGS. 9A and 9B. As illustrated, the waveguides 670, 680, 690, along with each waveguide's associated light distributing element 730, 740, 750 and associated out-coupling optical element 800, 810, 820, may be vertically aligned. However, as discussed herein, the in-coupling optical elements 700, 710, 720 are not vertically aligned; rather, the in-coupling optical elements are preferably non-overlapping (e.g., laterally spaced apart as seen in the top-down view). As discussed further herein, this nonoverlapping spatial arrangement facilitates the injection of light from different resources into different waveguides on a one-to-one basis, thereby allowing a specific light source to be uniquely coupled to a specific waveguide. In some embodiments, arrangements including nonoverlapping spatially-separated in-coupling optical elements may be referred to as a shifted pupil system, and the in-coupling optical elements within these arrangements may correspond to sub pupils.

FIG. 9D illustrates an example of wearable display system 60 into which the various waveguides and related systems disclosed herein may be integrated. In some embodiments, the display system 60 is the display system 250 of FIG. 6, with FIG. 6 schematically showing some parts of that system 60 in greater detail. For example, the waveguide assembly 260 of FIG. 6 may be part of the display 70.

With continued reference to FIG. 9D, the display system 60 includes a display 70, and various mechanical and electronic modules and systems to support the functioning of that display 70. The display 70 may be coupled to a frame 80, which is wearable by a display system user or viewer 90 and which is configured to position the display 70 in front of the eyes of the user 90. The display 70 may be considered eyewear in some embodiments. In some embodiments, a speaker 100 is coupled to the frame 80 and configured to be positioned adjacent the ear canal of the user 90 (in some embodiments, another speaker, not shown, may optionally be positioned adjacent the other ear canal of the user to provide stereo/shapeable sound control). The display system 60 may also include one or more microphones 110 or other devices to detect sound. In some embodiments, the microphone is configured to allow the user to provide inputs or commands to the system 60 (e.g., the selection of voice menu commands, natural language questions, etc.), and/or may allow audio communication with other persons (e.g., with other users of similar display systems. The microphone may further be configured as a peripheral sensor to collect audio data (e.g., sounds from the user and/or environment). In some embodiments, the display system may also include a peripheral sensor 120a, which may be separate from the frame 80 and attached to the body of the user 90 (e.g., on the head, torso, an extremity, etc. of the user 90). The peripheral sensor 120a may be configured to acquire data characterizing a physiological state of the user 90 in some embodiments. For example, the sensor 120a may be an electrode.

With continued reference to FIG. 9D, the display 70 is operatively coupled by communications link 130, such as by a wired lead or wireless connectivity, to a local data processing module 140 which may be mounted in a variety of configurations, such as fixedly attached to the frame 80, fixedly attached to a helmet or hat worn by the user, embedded in headphones, or otherwise removably attached to the user 90 (e.g., in a backpack-style configuration, in a belt-coupling style configuration). Similarly, the sensor 120a may be operatively coupled by communications link 120b, e.g., a wired lead or wireless connectivity, to the local processor and data module 140. The local processing and data module 140 may include a hardware processor, as well as digital memory, such as non-volatile memory (e.g., flash memory or hard disk drives), both of which may be utilized to assist in the processing, caching, and storage of data. Optionally, the local processor and data module 140 may include one or more central processing units (CPUs), graphics processing units (GPUs), dedicated processing hardware, and so on. The data may include data a) captured from sensors (which may be, e.g., operatively coupled to the frame 80 or otherwise attached to the user 90), such as image capture devices (such as cameras), microphones, inertial measurement units, accelerometers, compasses, GPS units, radio devices, gyros, and/or other sensors disclosed herein; and/or b) acquired and/or processed using remote processing module 150 and/or remote data repository 160 (including data relating to virtual content), possibly for passage to the display 70 after such processing or retrieval. The local processing and data module 140 may be operatively coupled by communication links 170, 180, such as via a wired or wireless communication links, to the remote processing module 150 and remote data repository 160 such that these remote modules 150, 160 are operatively coupled to each other and available as resources to the local processing and data module 140. In some embodiments, the local processing and data module 140 may include one or more of the image capture devices, microphones, inertial measurement units, accelerometers, compasses, GPS units, radio devices, and/or gyros. In some other embodiments, one or more of these sensors may be attached to the frame 80, or may be standalone structures that communicate with the local processing and data module 140 by wired or wireless communication pathways.

With continued reference to FIG. 9D, in some embodiments, the remote processing module 150 may include one or more processors configured to analyze and process data and/or image information, for instance including one or more central processing units (CPUs), graphics processing units (GPUs), dedicated processing hardware, and so on. In some embodiments, the remote data repository 160 may include a digital data storage facility, which may be available through the internet or other networking configuration in a “cloud” resource configuration. In some embodiments, the remote data repository 160 may include one or more remote servers, which provide information, e.g., information for generating augmented reality content, to the local processing and data module 140 and/or the remote processing module 150. In some embodiments, all data is stored and all computations are performed in the local processing and data module, allowing fully autonomous use from a remote module. Optionally, an outside system (e.g., a system of one or more processors, one or more computers) that includes CPUs, GPUs, and so on, may perform at least a portion of processing (e.g., generating image information, processing data) and provide information to, and receive information from, modules 140, 150, 160, for instance via wireless or wired connections.

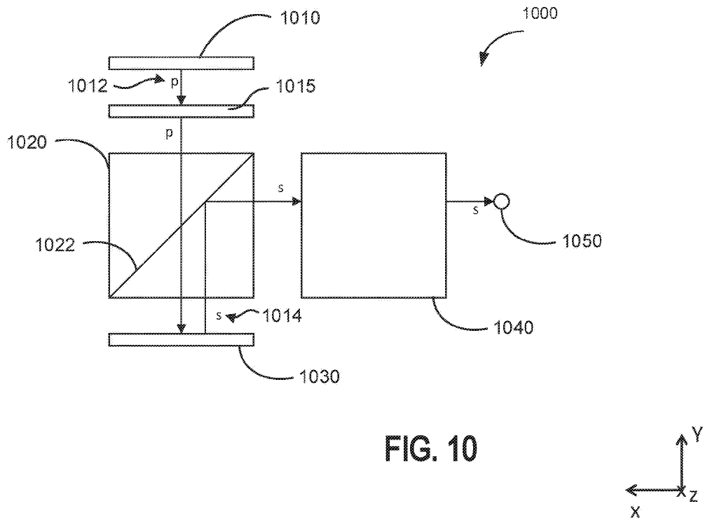

FIG. 10 is a schematic diagram illustrating a projector assembly 1000 that utilizes a polarization beamsplitter (PBS) 1020 to illuminate a spatial light modulator (SLM) 1030 and redirect the light from the SLM 1030 through projection optics 1040 to an eyepiece (not shown). The projector assembly 1000 includes an illumination source 1010, which can include, for example, light emitting diodes (LEDs), lasers (e.g., laser diodes), or other type of light source. This light may be collimated by collimating optics. The illumination source 1010 can emit polarized, unpolarized, or partially polarized light. In the illustrated design, the illumination source 1010 may emit light 1012 polarized having a p-polarization. A first optical element 1015 (e.g., a pre-polarizer) is aligned to pass light with the first polarization (e.g., p-polarization).

This light is directed to the polarizing beam splitter 1020. Initially, light passes through an interface 1022 (e.g., a polarizing interface) of the PBS 1020, which is configured to transmit light of the first polarization (e.g., p-polarization). Accordingly, the light continues to and is incident on the spatial light modulator 1030. As illustrated, the SLM 1030 is a reflective SLM configured to retro-reflect the light incident and selectively modulate the light. The SLM 1030, for example, includes one or more pixels that can have different states. The light incident on respective pixels may be modulated based on the state of the pixel. Accordingly, the SLM 1030 can be driven to modulate the light so as to provide an image. In this example, the SLM 1030 may be a polarization based SLM that modulates the polarization of the light incident thereon. For example, in an on state, a pixel of the SLM 1030 changes input light from a first polarization state (e.g., p-polarization state) to a second polarization state (e.g., s-polarization state) such that a bright state (e.g., white pixel) is shown. The second polarization state may be the first polarization state modulated (e.g., rotated) by 90°. In the on state, the light having the second polarization state is reflected by the interface 1022 and propagates downstream to the projector optics 1040. In an off state, the SLM 1030 does not change the polarization state of the light incident thereon, for example, does not rotate the input light from the first polarization state, thus a dark state (e.g., black pixel) is shown. In the off state, the light having the first polarization state is transmitted through the interface 1022 and propagates upstream back to the illumination source 1010 and not to a user's eye.

After reflection from the SLM 1030, a portion of the light 1014 (e.g., the modulated light) is reflected from the interface 1022 and exits the PBS 1020 to be directed to the user's eye. The emitted light passes through the projector optics 1040 and is imaged onto an in-coupling grating (ICG) 1050 of an eyepiece (not shown).

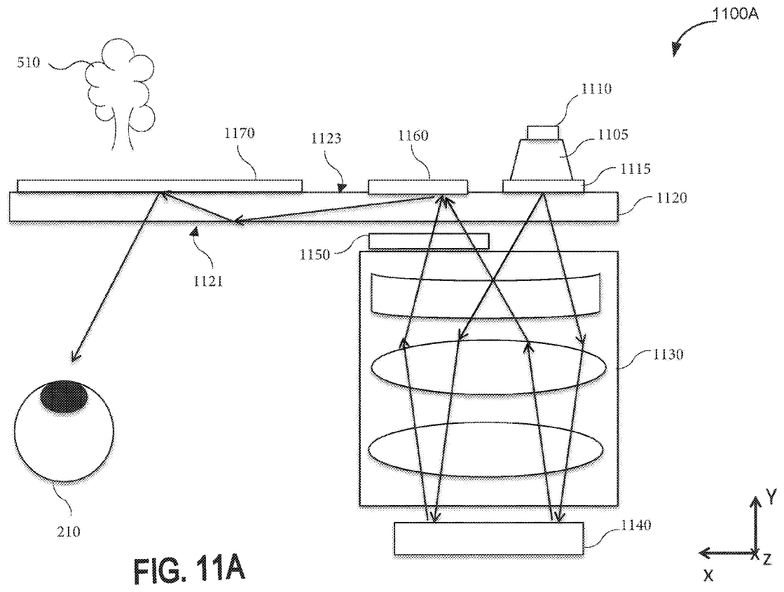

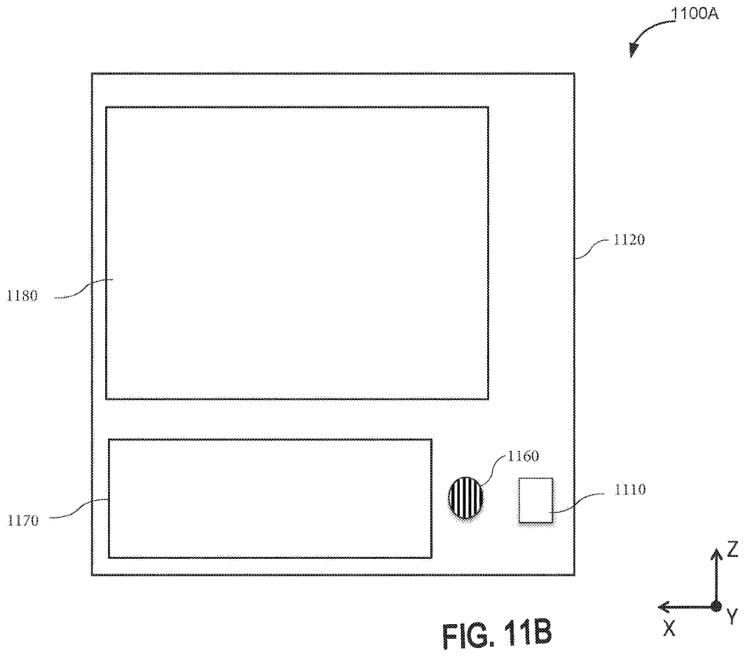

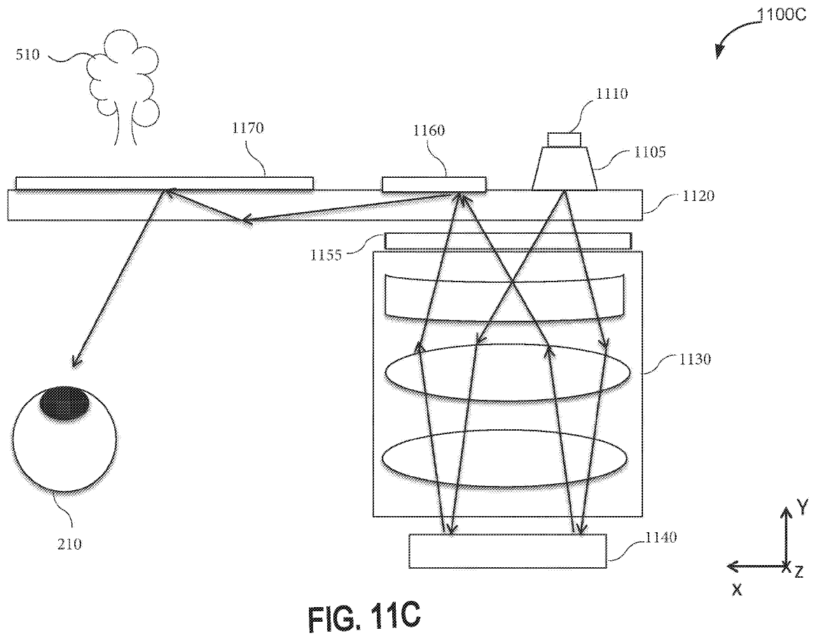

FIG. 11A illustrates a system (e.g., an augmented reality display system) 1100A for presenting images to the user's eye 210 and for viewing the world 510 that has an alternative configuration to that shown in FIG. 10. The system 1100 includes a light source 1110, a spatial light modulator (SLM) 1140, and a waveguide 1120 arranged such that light from the light source 1110 illuminates the SLM 1140, and light reflected from the SLM 1140 is coupled into the waveguide 1120 to be directed to the eye 210. The system 1100A includes optics 1130 disposed to both illuminate the SLM 1140 and project an image of the SLM 1140. Light from the light source 1110, for example, propagates in a first direction through the optics 1130 onto the SLM 1140 thereby illuminating the SLM 1140. Light reflected from the SLM 1140 propagates again through the optics 1130 in a second direction opposite the first direction and is directed to the waveguide 1120 and coupled therein.

The light source 1110 may include light emitting diodes (LEDs), lasers (e.g., laser diodes), or other type of light source. The light source 1110 may be a polarized light source, however the light source 1110 need not be so limited. In some implementations, a polarizer 1115 may be positioned between the light source 1110 and the SLM 1140. As illustrated, the polarizer 1115 is between the light source 1110 and the waveguide 1120. This polarizer 1115 may also be a light recycler, transmitting light of a first polarization and reflecting light of a second polarization back to the light source 1110. Such a polarizer 1115 may be, for example, a wire grid polarizer. A coupling optic 1105, such as a nonimaging optical element (e.g., cone, compound parabolic collector (CPC, lenses)), may be disposed with respect to the light source 1110 to receive light output from the light source 1110. The coupling optic 1105 may collect the light from the light source 1110 and may, in some cases, reduce the divergence of light emitted from the light source 1110. The coupling optic 1105 may, for example, collimate the light output from the light source 1110. The coupling optic 1105 may collect light that matches the angular spectrum field of view of the system 1100A. Accordingly, the coupling optic 1105 may match an angular spectrum of the light output by the light source 1110 with the field of view of the system 1100A. The coupling optic 1105 may have an asymmetric profile to operate on the light emitted from the light source 1110 asymmetrically. For example, the coupling optic 1105 may reduce the divergence a different amount in orthogonal directions (e.g., x and z directions). Such asymmetry in the coupling optic 1105 may address asymmetry in the light emitted from the light source 1110 which may include, for example, a laser diode that emits a wider range of angles of light in one direction (e.g., x or z) as opposed to the orthogonal direction (e.g., z or x, respectively).

As discussed above, the system 1100A includes optics 1130 configured to illuminate the SLM 1140 that is disposed in an optical path between the light source 1110 and the SLM 1140. The optics 1130 may include transmissive optics that transmits light from the light source 1110 to the SLM 1140. The optics 1130 may also be configured to project an image of the SLM 1140 or formed by the SLM 1140 into the waveguide 1120. An image may be projected into the eye of the eye 210. In some designs, the optics 1130 may include one or more lenses or optical elements having optic power. The optic 1130 may, for example, have positive optical power. The optics 1130 may include one or more refractive optical elements such as refractive lenses. Other types of optical elements may also possibly be used.

The SLM 1140 may be reflective, modulating and reflecting light therefrom. The SLM 1140 may be a polarization based SLM configured to modulate polarization. The SLM 1140 may, for example, include a liquid crystal (LC) SLM (e.g., a liquid crystal on silicon (LCOS) SLM). The LC SLM may, for example, include twisted nematic (TN) liquid crystal. The SLM 1140 may be substantially similar to the SLM 1030 with reference to FIG. 10. The SLM 1140 may, for example, include one or more pixels that are configured to selectively modulate light incident on the pixel depending on the state of the pixel. For some types of SLMs 1140, the pixel may, for example, modulate the beam incident thereon by altering the polarization state such as rotating the polarization (e.g., rotating the orientation of linearly polarized light).

As discussed above, the SLM 1140 may be a LCOS SLM 1140. In a cross-polarizer configuration, the LCOS SLM 1140 may be nominally white. When a pixel is off (e.g., 0 voltage), it has a bright state, and when the pixel is on (e.g., voltage above a threshold turn on voltage), it has a dark state. In this cross-polarization configuration, leakage is minimized when a pixel is on and it has a dark state.

In a parallel-polarizer configuration, the LCOS SLM 1140 is nominally black. When a pixel is off (e.g., 0 voltage), it has a dark state, and when the pixel is on (e.g., voltage above a threshold tum on voltage), it has a bright state. In this parallel-polarizer configuration, leakage is minimized when a pixel is off and it has a dark state. The dark state may be (re)optimized using rub direction and compensator angle. Compensator angle may refer to an angle of a compensator which may be between the optics 1130 and the SLM 1140.

Dynamic range and throughput for parallel-polarizer configurations may be different than that of cross-polarizer configurations. Further, parallel-polarizer configurations may be optimized for contrast differently than cross-polarizer configurations.

The system 1100A includes the waveguide 1120 for outputting image information to the eye 210. The waveguide 1120 may be substantially similar to waveguides 270, 280, 290, 300, 310, 670, 680, and 690 discussed above. The waveguide 1120 may include substantially transparent material having a refractive index sufficient to guide light therein. As illustrated, the waveguide 1120 may include a first side 1121 and a second side 1123 opposite the first side 1121 and corresponding upper and lower major surfaces as well as edges there around. The first and second major 1121, 1123 surface may be sufficiently flat such that image information may be retained upon propagating light from the SLM 1140 to the eye 210 such than an image formed by the SLM 1140 may be injected into the eye. The optics 1130 and the SLM 1140 may be positioned on the first side 1121 of the waveguide 1120. The light source 1110 may be disposed on the second side 1123 such that light from the light source 1110 is incident on the second side 1123 prior to passing through the waveguide 1120 and through the optics 1130 to the SLM 1140. Accordingly, the waveguide 1120 may be disposed between the light source 1110 and the optics 1130. Additionally, at least a portion of the waveguide 1120 may extend between the light source 1110 and the optics 1130, whereby light passes through the portion of the waveguide 1120 to the optics 1130. Light emitted from the light source 1110 can therefore be directed through the waveguide 1120, into and through the optics 1130 and incident on the SLM 1140. The SLM 1140 reflects the light back through the optics 1130 and to the waveguide 1120.

The system 1100A also includes an in-coupling optical element 1160 for coupling light from the optics 1130 into the waveguide 1120. The in-coupling optical element 1160 may be disposed on a major surface (e.g., an upper major surface 1123) of the waveguide 1120. In some designs, the in-coupling optical element 1160 may be disposed on the lower major surface 1121 of the waveguide 1120. In some designs, the in-coupling optical element 1160 may be disposed in the body of the waveguide 1120. While illustrated on one side or comer of the waveguide 1120, the in-coupling optical element 1160 may be disposed in/on other areas of the waveguide 1120. The in-coupling optical element 1160 may be substantially similar to the in-coupling optical elements 700, 710, 720 described above with reference to FIGS. 9A, 9B, and 9C. The in-coupling optical element 1160 may be a diffractive optical element or a reflector. Other structures may be used as the in-coupling optical element 1160. The in-coupling optical element 1160 may be configured to direct the light incident thereon into the waveguide 1120 at a sufficiently large grazing angle (e.g., greater than the critical angle) with respect to the upper and lower major surfaces 1123, 1121 of the waveguide 1120 to be guided therein by total internal reflection. Further, the in-coupling optical element 1160 may operate on a wide range of wavelengths and thus be configured to couple light of multiple colors into the waveguide 1120. For instance, the in-coupling optical element 1160 may be configured to couple red light, green light, and blue light into the waveguide 1120. The light source 1110 may emit red, green, and blue color light at different times.

The system 1100A includes a light distributing element 1170 disposed on or in the waveguide 1120. The light distributing element 1170 may be substantially similar to the light distributing elements 730, 740, and 750 described above with respect to FIG. 9B. For instance, the light distributing element 1170 may be an orthogonal pupil expander (OPE). The light distributing element 1170 may be configured to spread the light within the waveguide 1120 by turning the light propagating in the x direction, for example, toward the z direction illustrated in the top view FIG. 11B. The light distributing element 1170 may, thus, be configured to increase dimensions of the eyebox along the z-axis; see FIG. 11B. The light distributing element 1170 may, for example, include one or more diffractive optical elements configured to diffract the light propagating within the waveguide 1120 incident the diffractive optical elements so as to redirect that light, for example, in a generally orthogonal direction. Other configurations are possible.

As shown in FIG. 11B, the system 1100A may also include an out-coupling optical element 1180 for coupling light out of the waveguide 1120 to the eye 210. The out-coupling optical element 1180 may be configured to redirect light propagating within the waveguide 1120 by total internal reflection (TIR) at an angle more normal to the upper and/or lower major surfaces 1123, 1121 of the waveguide 1120 such that the light is not guided within the waveguide 1120. Instead, this light is directed out of the waveguide 1120 through, for example, the lower major surface 1121. The out-coupling optical element 1180 may, for example, include one or more diffractive optical elements configured to diffract the light propagating within the waveguide 1120 incident the diffractive optical element so as to redirect that light, for example, out of the waveguide 1120. Other configurations are possible.

FIG. 11B also shows the location of the in-coupling optical element 1160 laterally disposed with respect to the light distributing optical element (e.g., orthogonal pupil expander) 1170 and the out-coupling optical element 1180. FIG. 11B also shows the location of the light source 1110 laterally disposed with respect to the in-coupling optical element 1160, the light distributing optical element (e.g., orthogonal pupil expander) 1170, and the out-coupling optical element 1180.

In operation, the light source 1110 of the system 1100A emits light into the coupling optic 1105 and through the polarizer 1115. This light may therefore be polarized, for example, linearly polarized in a first direction. This polarized light may be transmitted through the waveguide 1120, entering the second major surface of the waveguide 1120 and exiting the first major surface of the waveguide 1120. This light may propagate through the optics 1130 to the SLM 1140. The optics 1130 quasi-collimates and/or selects the light from the light source 1110 to thereby illuminate the SLM 1140, which may include a polarization based modulator that modulates the polarization of light incident thereon such as by selectively rotating the orientation of the modulator on a pixel by pixel basis depending on the state of the pixel. For example, a first pixel may be in a first state and rotate polarization while a second pixel may be in a second state and not rotate polarization. The light between the coupling optic 1105 and the optics 1130 may fairly uniformly illuminate the SLM 1140. After being incident on the SLM 1140, the light is reflected back through the optics 1130. The optics 1130 may be configured to project images from the SLM 1140 into the waveguide 1120 and ultimately into the eye 210 so that the image is visible to the eye 210. In some designs, the retina of the eye 210 is the optical conjugate to the SLM 1140 and/or images formed by and/or on the SLM 1140. The power of the optics 1130 may facilitate the projection of the image on the SLM 1140 into the eye 210 and onto the retina of the eye 210. In some implementations, optical power, for example, provided by the out-coupling optical element 1180 may assist in and/or affect the image ultimately formed in the eye 210. The optics 1130 acts as a projection lens as light reflected from the SLM 1140 travels through the optics toward the waveguide 1120. The optics may function roughly as a Fourier transform of the image on the SLM 1140 to a plane in the waveguide 1120 near the in-coupling optical elements 1160. Together, both passes through the optics 1130 (a first from the light source 1110 to the SLM 1140, and a second from the SLM 1140 to the waveguide 1120) may act to roughly image pupils of the coupling optic 1105. The alignment and orientation of the light source 1110 (possibly also coupling optic 1105 and/or the polarizer 1115), the optics 1130, the SLM 1140 are such that light from the light source 1110 that is reflected from the SLM 1140 is directed onto the in-coupling optical element 1160. The pupil associated with the coupling optic 1105 may be aligned with the in-coupling optical element 1160. The light may pass through the analyzer 1150 (e.g., a polarizer) in an optical path between the SLM 1140 and the eye 210. As depicted in FIG. 11A, an analyzer (e.g., polarizer) 1150 may be disposed in an optical path between the optics 1130 and the in-coupling optical element 1160. The analyzer 1150 may, for example, be a linear polarizer having an orientation to transmit light of the first polarization (p-polarization) and block light of the second polarization (s-polarization) or vice versa. The analyzer 1150 may be a clean-up polarizer and further block light of a polarization that is blocked by another polarizer between the SLM 1140 and the analyzer 1150 or within the SLM 1140. The analyzer 1150 may, for example, be a circular polarizer that acts as an isolator to mitigate reflections from the waveguide 1120, specifically the in-coupling optical element 1160, back toward the SLM 1140. The analyzer 1150 may, as any of the polarizers disclosed herein, include wire grid polarizers such as an absorptive wire grid polarizer. Such polarizers may offer appreciable absorption of unwanted light and therefore increased contrast. Some such polarizers can be made to include one or more dielectric layers on top of the wires and/or multilayer films. In some implementations the SLM 1140 may be a liquid crystal on silicon (LCOS) SLM and may include LC cells and a retarder (e.g., compensator). In some implementations, the analyzer 1150 may be a compensator intended to provide a more consistent polarization rotation (e.g., of 90°) of the SLM 1140 for different angles of incidence and different wavelengths. A compensator may be used to improve contrast of the display by improving the rotation polarization for rays that are incident across a spread of angles and wavelengths. The SLM 1140 may include, for example, a TN LCOS that is configured to rotate incident light of a first polarization (e.g., s-polarization) to a second polarization (e.g., p-polarization) for a first pixel to produce a bright pixel state as the light will pass through the analyzer 1150. Conversely, the SLM 1140 may be configured to not rotate incident light of the first polarization (e.g., s-polarization) to the second polarization (e.g., p-polarization) for a second pixel such that the reflected light remains the first polarization to produce a dark pixel state as the light will be attenuated or blocked by the analyzer 1150. In such a configuration, the polarizer 1115 closer along the optical path to the light source 1110 may be oriented different (e.g., orthogonal) to the analyzer 1150 farther along the optical path from the light source 1110. Other, for example, opposite, configurations are possible. The light is then deflected, for example, turned by the in-coupling optical element 1160, so as to be guided in the waveguide 1120 where it propagates by TIR. The light then impinges on the light distributing element 1170 turning the light in another direction (e.g., more towards the z direction) causing an increase in dimensions of an eyebox along the direction of the z-axis as shown in FIG. 11B. The light is thus deflected toward the out-coupling optical element 1180 which causes the light to be directed out of the waveguide 1120 toward the eye 210 (e.g., the users eye as shown). Light being coupled out by different portions of the out-coupling optical element 1180 along the z direction causes an increase in dimensions of the eyebox along at least the direction parallel to the z-axis as defined in FIG. 11B. Notably, in this configuration, the optics 1130 are used both for illuminating the SLM 1140 and projecting an image onto the in-coupling optical element 1160. Accordingly, the optics 1130 may act as projection optics distributing light from the light source 1110 (e.g., uniformly) as well as imaging optics providing an image of the SLM 1140 and/or of an image formed by the SLM 1140 into the eye.

As referred to above, alternative configurations are possible. With reference to FIG. 11C, for example, in some designs, a system 1100C may be configured to pass light having a polarization not rotated by the SLM 1140. In one implementation, for example, the SLM 1140 be a liquid crystal (LC) based SLM and may include vertically aligned (VA) LC on silicon (LCOS). The SLM 1140 may have a first pixel that is in a first state that does not rotate the polarization and a second pixel that is in a second state that rotates the polarization. In the configuration illustrated in FIG. 111C, a single shared analyzer/polarizer 1155 is utilized. This analyzer 1155 may transmit light of a first polarization (e.g., s-polarization) and attenuate or reduce transmission of a second polarization (e.g., p-polarization). Accordingly, light (e.g., s-polarized light) incident on a first pixel in the first state that does not rotate the polarization orientation is reflected from the SLM 1140 and passes through the analyzer 1155 to the waveguide 1120. Conversely, light (e.g., s-polarized light) incident on the second pixel in the second state that rotates the polarization orientation is reflected from the SLM 1140 and attenuated, reduced, or not passed through the analyzer 1155 to the waveguide 1120. This configuration, may thereby permit the polarizer 1115 and the analyzer 1150 shown in FIG. 11A to be incorporated into a shared optical element, the analyzer 1155 shown in FIG. 11C, thereby possibly simplifying the system 1100 of FIG. 11A/B by reducing the number of optical components. The analyzer 1155 may be disposed between the waveguide 1120 and the optics 1130. In other implementations, a separate analyzer/polarizer and analyzer/polarizer may be used such as shown in system 1100 of FIG. 11A/B. FIGS. 11A and 11B illustrate the polarizer 1115 between the light source 1110 and the waveguide 1120, and the analyzer 1140 between the optics 1130 and the waveguide 1120.

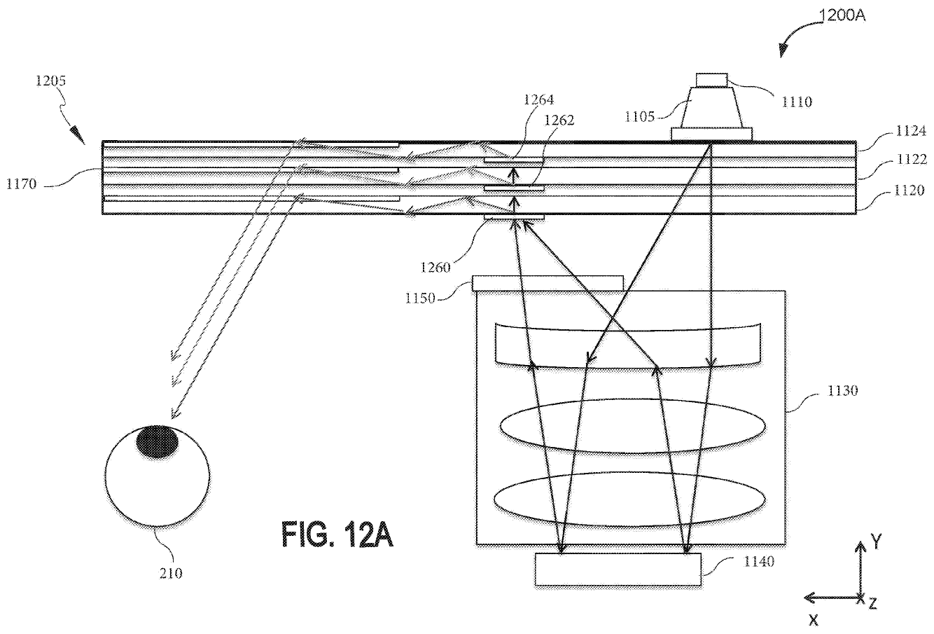

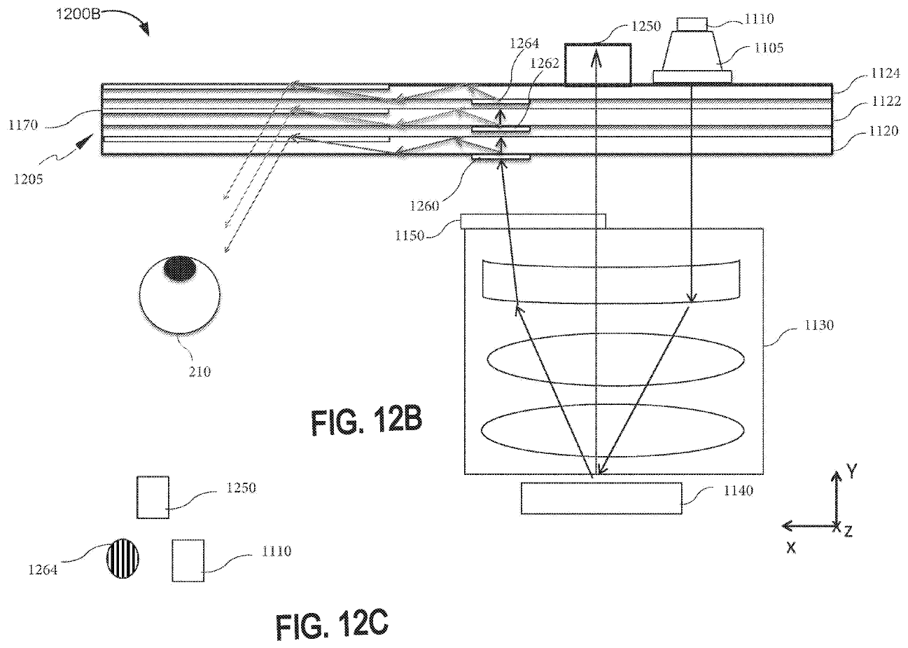

A wide variety of other configurations may be employed that utilize the optics 1130 for both illumination of the SLM 1140 and imaging of the image formed by the SLM 1140. For example, although FIGS. 12A-12C show a single waveguide 1120, one or more waveguides such as a stack of waveguide (possibly different waveguides for different color light) may be used. FIG. 12A, for example, illustrates a cross-sectional side view of an example system 1200A including a stack 1205 including waveguides 1120, 1122, 1124 that each includes an in-coupling optical element 1260, 1262, 1264. The waveguides 1120, 1122, 1124 may each be configured to output light of one or more different wavelengths, or one or more different ranges of wavelengths. The stack 1205 may be substantially similar to the stack 260 and 660 (FIGS. 6 and 9A) and the illustrated waveguides 1120, 1122, 1124 of the stack 1205 may correspond to part of the waveguides 670, 680, 690, however, the stack 1205 and waveguides 1120, 1122, 1124 need not be so limited. As illustrated in FIG. 12A, the in-coupling optical elements 1260, 1262, 1264 may be, for example, associated with, included in or on the waveguides 1120, 1122, 1124, respectively. The in-coupling optical elements 1260, 1262, 1264 may be color selective and may primarily divert or redirect certain wavelengths into the corresponding waveguides 1120, 1122, 1124 to be guided therein. As illustrated, because the in-coupling optical elements 1260, 1262, 1264 are color selective, the in-coupling optical elements 1260, 1262, 1264 need not be laterally displaced and may be stacked over each other. Wavelength multiplexing may be employed to couple the particular color into the corresponding waveguide. For example, the red in-coupling optical element may in-couple red light into the waveguide designated for propagating red light while not in-coupling blue or green light, which is coupled instead into the other waveguides by the other blue and green color selective waveguides, respectively.

In some implementations, the light source 1110 may be a multi-color light source capable of emitting different colored light at different times. For instance, the light source 1110 may emit red, green, and blue (RGB) light and may be configured to, at a first time period emit red and not more than negligible amounts of green and blue, at a second time period emit green and not more than negligible amounts of red and blue, and at a third time period emit blue and not more than negligible amounts of red and green. These cycles can be repeated and the SLM 1140 can be coordinated so as to produce the suitable pattern of pixel states for the particular color (red, green, or blue) to provide the proper image color component for a given image frame. The different waveguides 1120, 1122, 1124 of the stack 1205 may each be configured to output light with different respective colors. For example, as depicted in FIG. 12A, the waveguides 1120, 1122, 1124 may be configured to output blue, green, and red color light respectively. Of course, other colors are possible, for example, the light source 1110 may emit other colors and the color selective in-coupling optical element 1260, 1262, 1264, out-coupling optical element etc., can be configured for such other colors. Additionally, individual red, green, and blue emitters may be located close enough in proximity to effectively function as a single pupil light source. The red, green, and blue emitters may be combined with lenses and dichroic splitters to form a single red, green, and blue pupil source. The multiplexing of a single pupil may be extended beyond, or in addition to, color selectivity and may include the use of polarization sensitive gratings and polarization switching. These color or polarization gratings can also be used in combination with multiple display pupils to increase the number of layers that can be addressed.

The different in-coupling optical elements 1260, 1262, 1264 in the different waveguides 1120, 1122, 1124 may be disposed over and/or under and aligned laterally with respect to each other (e.g., in the x and z directions shown in FIG. 12A) as opposed to being laterally displaced with each other and not aligned. Accordingly, in some implementations, for example, the different in-coupling optical elements 1260, 1262, 1264 can be so configured such that light of a first color can be coupled by the in-coupling optical element 1260 into waveguide 1120 to be guided therein and light of a second color different from the first color can pass through the in-coupling optical element 1260 to the next in-coupling optical element 1262 and can be coupled by the in-coupling optical element 1262 into the waveguide 1122 to be guided therein. Light of a third color different from the first color and the second color can pass through in-coupling optical elements 1260 and 1262 to the in-coupling optical element 1264 and can be coupled into the waveguide 1124 to be guided therein. Additionally, the in-coupling optical elements 1260, 1262, 1264 may be polarization selective. For example, the different in-coupling optical elements 1260, 1262, 1264 can be so configured such that light of a certain polarization either is coupled into the waveguide by a corresponding polarization selective in-coupling optical element 1260, 1262, 1264 or passes through the in-coupling optical element 1260, 1262, 1264.

Depending on the configuration, the SLM 1140 may include a polarization based SLM that modulates the polarization. The system 1200A can include polarizers and/or analyzers so as to modulate the light injected into the stack 1205 on a pixel by pixel basis, for example, depending on the state of the respective pixel (e.g., whether the pixel rotates the polarization orientation or not). Various aspects of such systems that employ polarization based SLMs are discussed above and any one of such features may be employed in combination with any other features described herein. Other designs, however, are still possible.

For example, a deflection-based SLM 1140 may be employed. For example, the SLM 1140 may include one or more moveable optical elements such as a moveable mirror that can reflect and/or deflect light along different directions depending on the state of the optical element. The SLM 1140 may, for example, include one or more pixels including such optical elements such as micro-mirrors or reflectors. The SLM 1140 may incorporate, for example, Digital Light Processing (DLPTM) technology which uses digital micromirror devices (DMD). An example of a system 1200B that uses such a deflection-based SLM 1140 is shown in FIG. 12B. The system 1200B includes a deflection based SLM 1140 as well as a light dump 1250. The light dump 1250 may include an absorbing material or structure that is configured to absorb light. The deflection-based SLM 1140 may include one or more micro moveable mirrors that can be selectively tilted to deflect light in different directions. For example, the deflection based SLM 1140 may be configured to deflect light from the light source 1110 incident thereon to the in-coupling optical elements 1260, 1262, 1264 when a given pixel is in a bright state. As discussed above, this light will thus be coupled by one of the in-coupling optical elements 1260, 1262, 1264, for example, depending on the color of light, into one of the respective waveguides 1120, 1122, 1124 and directed to the eye 210. Conversely, when a given pixel is in a dark state, light from the light source 1110 may be deflected to the light dump 1250 and the light is not coupled by one of the in-coupling optical elements 1260, 1262, 1264 into one of the respective waveguides 1120, 1122, 1124 and directed to the eye 210. The light may instead be absorbed by absorbing material including the light dump 1250. In some implementations, the analyzer 1150 may be a polarizer (e.g., “clean-up” polarizer) used to eliminate undesired reflections from the in-coupling optical elements 1260, 1262, 1264. This polarizer may be useful as the optics 1130 may include plastic optical elements, which have birefringence and may alter polarization. A “clean-up” polarizer may attenuate or remove light (e.g., reflections) having unwanted polarization from being directed onto the waveguides 1120, 1122, 1124. Other types of light conditioning elements may be disposed between the SLM 1140 and the waveguides 1120, 1122, 1124 such as between the optics 1130 and the waveguides 1120, 1122, 1124. For example, such a light conditioning element may also include a circular polarizer (i.e., linear polarization and retarder such as a quarter waveplate) . The circular polarizer may reduce the amount of reflection from the waveguides 1120, 1122, 1124 or in-coupling optical elements 1260, 1262, 1264 that are again incident on the waveguides 1120, 1122, 1124 and coupled therein. Reflected light may be circular polarized and may possess a circular polarization opposite to that of the incident light (e.g., right-handed circularly polarizer light is converted to left-handed circular polarized light, or vice versa, upon reflection). The retarder in the circular polarizer may convert the circular polarized light to linearly polarized light, such as of the orthogonal polarization of the polarizer, which is attenuated, e.g., absorbed, by the linear polarizer in the circular polarizer. The clean-up polarizer may be used with a polarization independent modulator such as a DMD. As mentioned above, the clean-up polarizer may be useful for suppressing reflections and/or improving coupling of light into the in-coupling optical elements 1260, 1262, 1264 with optimal polarization states.

FIG. 12B illustrates a side or cross-sectional view of such the system 1200B, while FIG. 12C shows a top view of the lateral arrangement of the in-coupling optical element 1264, the light dump 1250, and the light source 1110. The SLM 1140 would be configured, depending on the state of the particular pixel, to reflect, deflect, and/or direct the light from the light source 1110 to either the lateral location of the in-coupling optical element 1264 (as well as the other in-coupling optical elements 1260, 1262) or the light dump 1250.

### Optical Systems With Dummy Regions

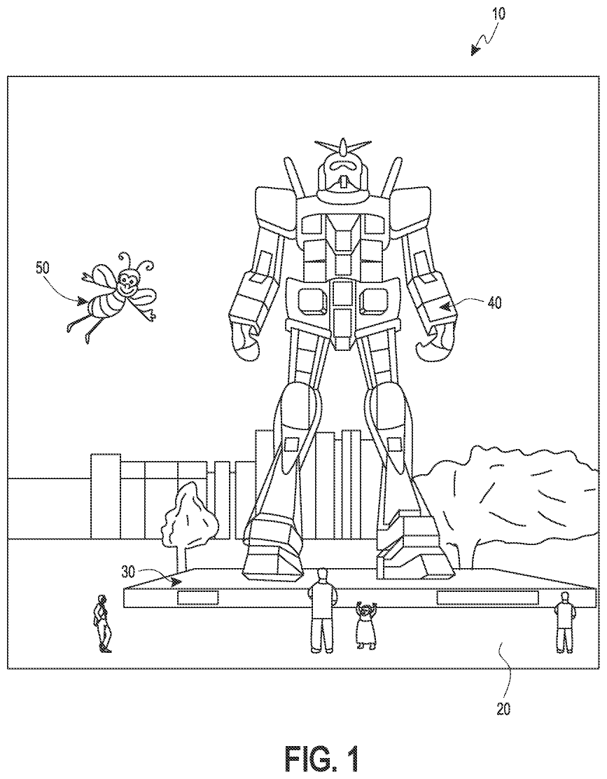

Imprinting processes, such as nanoimprint lithography (NIL), can be used to form optical structures such as diffraction gratings and other diffractive optical elements. These optical structures can be included in VR systems, AR systems, and other types of display and/or projection systems, such as the systems discussed above in reference to FIGS. 1-12C.

Optical system performance (e.g., light in-coupling/out-coupling efficiency) may be impaired by defects in imprinted structures. For example, in some cases, grating delamination and/or other damage can be observed on the edges (e.g., the leading/trailing edges) of imprinted patterns such as gratings. Such defects may be worse when the gratings extend perpendicular to the separation direction during the imprinting process.

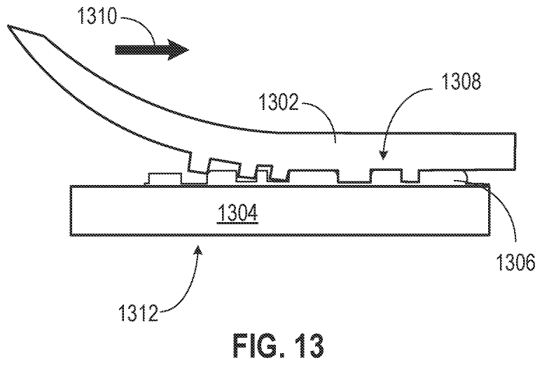

For example, FIG. 13 shows an imprinting process using a soft mold 1302 on a substrate 1304 (e.g., a semiconductor wafer or dielectric substrate) with a coating 1306 (e.g., a UV-curable polymer). A pattern in a face of the mold 1302 forms a corresponding pattern 1308 (in this example, a grating) in the coating 1306. As imprinting is performed with a rolling direction (imprint direction) 1310, separation occurs at approximately location 1312, and the separation is associated with separation forces (sometimes referred to as demolding forces), e.g., shearing force. Solid mold (“hard to hard”) imprint processes (e.g., solid mold NIL processes) may, in some cases, exhibit even higher shearing force than is observed with use of a soft mold. Separation forces can result in defects, especially at the edges of gratings and other imprinted patterns. For example, at a boundary between a pattern-rich region and a blank region, a spike in demolding forces may occur (e.g., a jerking-like force), and this spike in forces may shear off patterns, leading to imprinting defects.

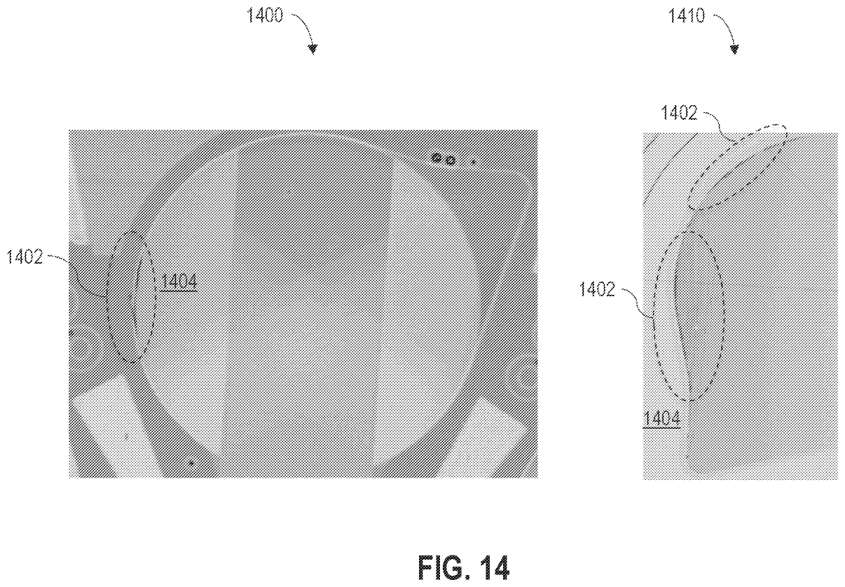

For example, FIG. 14 shows imprinted optical structures 1400, 1410 that exhibit delaminated gratings 1402 (observed as dark lines) at edges of grating areas 1404. In this case, delamination is observed at the leading edge (where the separation starts first during nanoimprint lithography imprint processes); however, delamination and other defects may occur at other edges, such as the trailing edge.

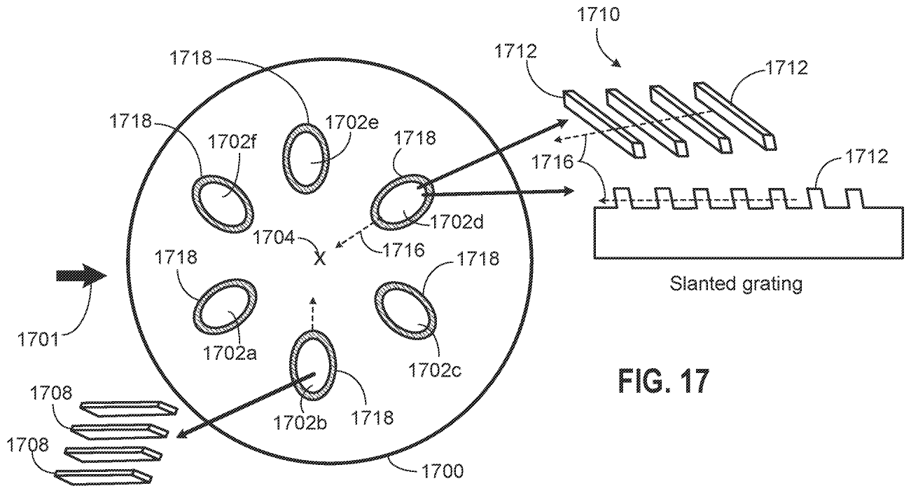

In some cases, defects are more likely to occur when the grating extends perpendicular to the separation/demolding direction. In addition, defects may be worse in the context of slanted gratings, in which the gratings are tilted from the normal direction to the surface. The slanted grating may cause significantly increased shearing force when the gratings are not lined up with the separation direction (such as in a pinwheel arrangement, as discussed below in reference to FIG. 17).

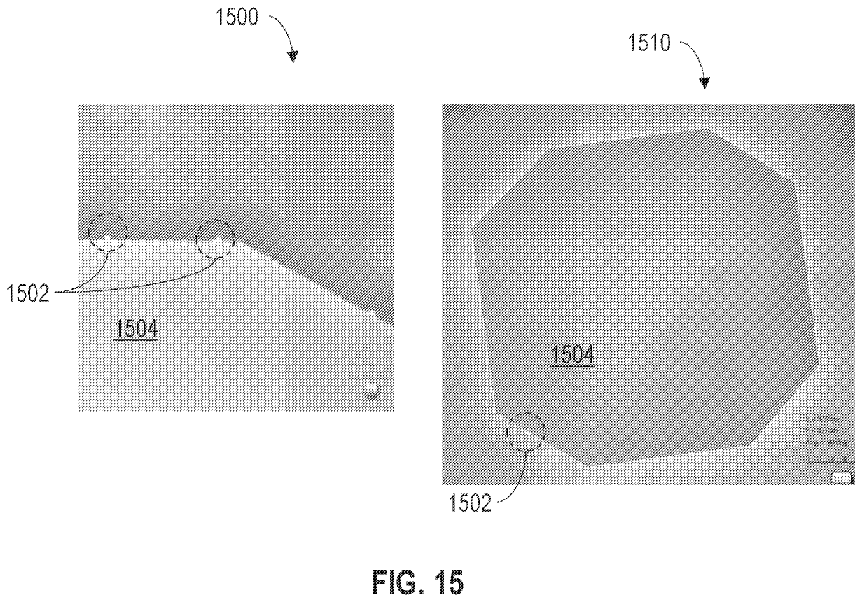

As another example, bubble formation may occur at the edge of patterned regions, such as grating regions, when running imprinting processes (e.g., especially high-speed imprinting processes). During the imprinting processes, air may be trapped at the edges, resulting in the bubbles. For example, FIG. 15 shows imprinted optical structures 1500, 1510 that exhibit bubbles 1502 at the edges of active regions 1504. Bubbles may cause optical performance degradation of waveguides, gratings, and other active optical structures.

According to some implementations of this disclosure, in order to mitigate grating delamination and/or other defects, a dummy imprinted area, such as a non-active grating zone, is added, adjacent to active pattern(s) such as active gratings. The dummy imprinted area is formed in a common imprinting process with the active area, e.g., using a common mold. As a result, fabrication-associated defects associated with pattern edges are kept spatially separated from the active patterns to obtain defect-free or relatively low-defect active patterns. For example, the separation edges where the imprinting mold first separates from the imprinted material (e.g., polymer) during the imprinting process can be located at an edge of a dummy imprinted area such as a non-active grating region, thus reducing or preventing damage to an active grating area adjacent to the dummy imprinted area.

As another example, because bubbles have been observed to form at the boundary between a grating and a blank (e.g., non-imprinted) region, a non-active dummy imprinted region can be provided adjacent to the grating, so that the patterned/blank interface is spatially separated from the grating. As a result, bubbles (should any form during imprinting) are more likely to occur in the non-active dummy imprinted region, thus mitigating the impact of bubbles on the optical performance of the grating.

In addition, in some implementations, the non-active dummy imprinted region can include one or more non-active structures that reduce and/or spread-out separation forces, e.g., based on orientations and/or feature heights of the non-active structures. As such, in some implementations, separation-induced damage can be not only shifted away from active structures but also reduced.

In some implementations, the non-active regions discussed herein can function as barriers to prevent residual layer thickness (RLT) shortage/defects due to the resist overflow at the grating edge. For example, in some cases, a volume of resist in a pattern-rich region (e.g., which may require a large resist volume) flows due to normal capillary action towards a blank area (e.g., with less resist volume), which can “starve” the pattern-rich area of resist, causing the pattern-rich area to have insufficient resist volume pre-cure, thus leading to non-fill defects, clogging, and/or peeling, e.g., because a residual interconnecting layer may be formed between structures and cause sticking to the template. In some implementations, the presence of a dummy imprinted region can reduce this flow (e.g., because flow from a pattern-rich region to a dummy imprinted region having a non-diffractive or sub-diffractive structure can be less than flow from a pattern-rich region to a blank region).

In some implementations according to the present disclosure, the “active” region is a diffractive region having one or more diffractive optical structures, and the “non-active region” is an optically non-diffractive or an optically-sub-diffractive region. For example, in some implementations, the non-active region can (but need not) include one or more structures that may perform one or more optical functions, such as anti-reflection, but that do not perform diffractive optical functions (e.g., light in-coupling/out-coupling using gratings) for light wavelength(s) for which the active region is diffractive. Whether the optical structures/nanostructures perform diffractive functions or non/sub-diffractive functions can be based at least on critical dimensions of the structures, such as grating dimensions (e.g., depth, width, and/or spacing). Accordingly, references throughout this disclosure to “active” regions and/or structures can, in some implementations, refer to “diffractive” regions and/or structures, and references to “non-active,” “dummy,” etc., regions and/or structures can refer to “non-diffractive” or “sub-diffractive” regions and/or structures.

In some implementations, the non-active dummy region is a non-active grating region having an imprinted grating. The non-active gratings may have geometry (grating orientation, pitch, critical dimensions such as width and/or height, duty cycle, and/or another parameter) that are significantly different from the active gratings, e.g., so that the non-active gratings will not interact diffractively with light having a wavelength that interacts diffractively with diffractive structures in active grating regions.

For example, in some implementations, an optically-diffractive structure, such as a grating, is configured to in-couple light into a waveguide (e.g., air-to-substrate) and/or out-couple light from a waveguide (e.g., substrate-to-air), the light being directed in total internal reflection (TIR). Light having the same wavelength may not interact diffractively with a non-active grating adjacent to the optically-diffractive structure, such that the non-active grating does not substantially or at all actively change the optical performance of the active region.

For example, in some implementations, the pitch of the grating(s) of the non-active region can be much larger or smaller than the pitch of grating(s) of the active region, and the different pitches can result in different optical interactions by the gratings (e.g., sub-diffractive for the non-active region and diffractive for the active region).

For example, in some implementations, the diffractive structure has a pitch (periodicity on one or two axes) between 200 nm and 1 μm or between 200 nm and 2 μm, and the sub-diffractive structure has a pitch of 100 nm or less, 200 nm or less, 300 nm or less, or 400 nm or less, and, for example, a pitch of greater than 20 nm or greater than 50 nm, dimensions that can provide diffractive and sub-diffractive behavior, respectively, for visible light. In some implementations, the diffractive structure has a pitch between 200 nm and 1 μm or between 200 nm and 2 μm, and the non-active structure has a pitch of 1 μm or more, a pitch of 2 μm or more, or a pitch of 3 μm or more. In some implementations, the active structure has a value of a parameter (e.g., pitch) that causes the diffractive structure to interact diffractively with one or more types of light, and the non-active structure has a value of the parameter that causes the non-active structure to not interact diffractively with the one or more types of light, where the one or more types of light can include visible light, infrared light, and/or ultraviolet light. In some implementations, the active structure has a value of a parameter (e.g., pitch) that causes the diffractive structure to in-couple and/or out-couple light through the diffractive structure to and/or from an underlying substrate, and the non-active structure has a value of the parameter that does not cause the non-diffractive structure to in-couple and/or out-couple light through the non-diffractive structure to and/or from the underlying substrate.

“Pitch” and other characterizations of patterned structures, as used herein, can refer not only to strict periodicity but also quasi-periodicity, e.g., tiles/arrays of structures with gradated heights or gradated orientations.

The use of a grating or other structure with a defined pattern as a non-active/dummy structure can, in some implementations, provide advantages compared to the use of another type of structure, e.g., a random structure. For example, a grating can be oriented to provide a relatively small demolding force (e.g., by having structures of the grating extending in the direction of peel), and/or to direct the demolding force gradually, e.g., by having multiple zones with different heights and/or grating directions. By contrast, a random structure may result in unpredictable, and potentially high, demolding forces depending on the random structure.

As described above, in some implementations the non-active structures (e.g., non-active gratings) perform one or more optical functions in a non-diffractive or sub-diffractive manner. For example, in some implementation, the non-active gratings are configured to perform anti-reflection, and/or the non-active regions can include an anti-reflection coating. For example, the geometry of a grating in a non-active region can be such that the grating interacts with light sub-diffractively or non-diffractively, e.g., by having one or more dimensions larger and/or smaller than corresponding dimensions of a diffractive grating in the active region.

The distance between a non-active structure and an adjacent active structure is sufficiently small to reduce or prevent imprinting-related defects that would otherwise occur on or at an edge of the active structure. For example, in various implementations, a distance between a non-active structure and an adjacent active structure can be less than 10 nm, less than 25 nm, less than 50 nm, less than 100 nm, less than 250 nm, less than 500 nm, less than 1 μm, less than 5 μm, less than 20 μm, less than 50 μm, or another value. In some implementations, the distance is very small, e.g., within the smallest resolution of electron-beam lithography or another process used to fabricate the template.

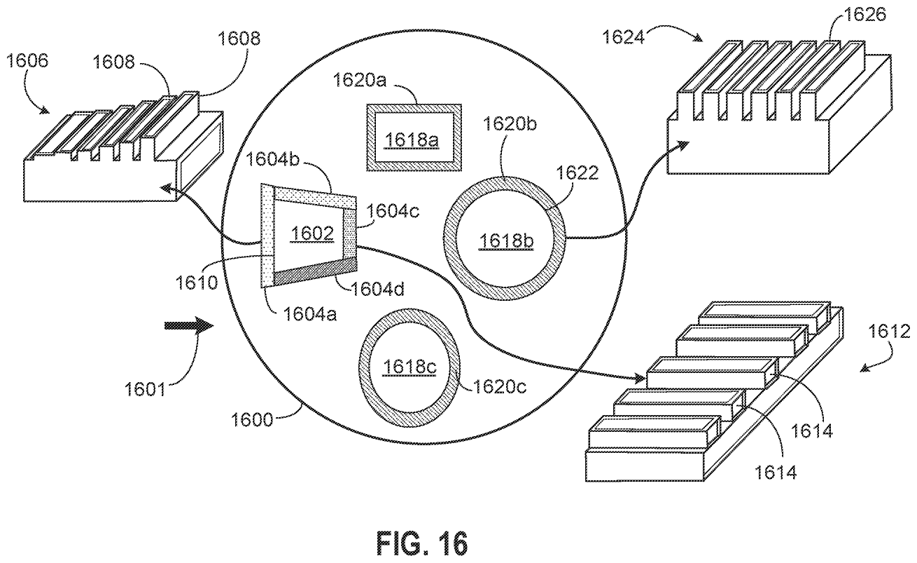

FIG. 16 illustrates several examples of non-active regions, in this case including non-active gratings, adjacent to active regions. In this example, for conciseness, all regions are disposed on a common substrate 1600; however, in general, a non-active region and active region need not be disposed on a substrate with other non-active regions and active regions. The structures of the non-active regions and active regions are formed in an imprinting process with an imprint direction 1601, which is parallel to the separation direction.

As shown in FIG. 16, active region 1602 is adjacent to non-active regions 1604a, 1604b, 1604c, 1604d, collectively referred to as non-active regions 1604. The non-active regions 1604 can have the same or different types of structures (e.g., sub-diffractive and/or non-diffractive structures). In this example, non-active region 1604a include a gradated non-active grating 1606. The non-active grating 1606 includes parallel-extending walls 1608 separated by trenches. In any of the implementations described herein, the walls of a grating (e.g., a sub-diffractive grating) of a non-active region can-though need not-extend parallel to walls of a grating of an adjacent active region, e.g., the walls 1608 can extend parallel to walls of a diffractive grating of active region 1602 (not shown). In some implementations, as shown in FIG. 16, the walls 1608 extend parallel to a boundary 1610 between the non-active region 1604a and the active region 1602. In some implementations, as shown in this example, the walls 1608 extend orthogonal to the imprint direction 1601.

The non-active grating 1606 is “gradated” in the sense that heights of the walls 1608 increase in the direction of the adjacent active region 1602, e.g., walls 1608 closer to the active region 1602 are taller than walls 1608 further from the active region 1602. The gradation can apply to all walls 1608 (e.g., such that the non-active grating 1606 has walls 1608 with heights monotonically increasing towards the active region 1602) or can apply to a subset of the walls 1608. For example, multiple adjacent walls 1608 in the non-active grating 1606 (e.g., two or more adjacent walls 1608, three or more adjacent walls 1608, four or more adjacent walls 1608, or another number of multiple adjacent walls 1608, in various implementations) can have heights increasing toward the adjacent active region 1602.

In some implementations, gradation can help guide the imprint force direction as well as guide demolding force direction so as to prevent a “sudden”, spatially-concentrated demolding force at the edge/boundary between the active diffractive and the sub-diffractive non-active region.

In some implementations, the gradated heights (or other gradated dimension) of a non-active structure approach the corresponding height (or other dimension) of the adjacent active structure. For example, a grating adjacent to the non-active grating 1606 in the active region 1602 can have height h, and heights of features—such as grating walls-of the non-active grating 1606, in order approaching the active region 1602, can be h₁<h₂< . . . <hₙ, where hₙ is less than or equal to h and can be, in some implementations, close to h, e.g., within 10% or 20% of h, or matching h. For example, the heights of features in the non-active region 1604 can be gradually taller leading up to the active region 1602. As such, the demolding force can be gradually guided/reduced to potentially decrease occurrence separation defects.

In some implementations, one or more parameters are gradated instead of, or in addition to, height. The parameter(s) can include, for example, feature height or depth, feature spacing, feature width, feature length, feature density, orientation (e.g., array angle with respect to a given direction), and/or array pitch and/or duty cycle in one or more dimensions. In some implementations, the gradation occurs in the imprint direction, which need not be the same as the direction towards an adjacent active region.

Another of the non-active regions 1604 adjacent to the active region 1602, non-active region 1604c, includes a grating 1612 composed of parallel walls 1614. In this example, the walls 1614 extend parallel to the separation direction of the imprinting process. In some implementations, this orientation of non-active structures—features, such as grating walls, extending parallel to the separation direction—can reduce occurrence of imprinting defects, e.g., by decreasing the shearing force during imprinting.

The other non-active regions 1604b, 1604d adjacent to the active region 1602 can include respective non-active gratings, which can have characteristics as described for non-active grating 1606 (e.g., with walls extending parallel to the boundary with the active region 1602, and/or with gradation of feature heights), and/or characteristics as described for non-active grating 1612 (e.g., with walls extending orthogonal to the boundary with the active region 1602, with walls extending parallel to the separation direction, and/or with no gradation in the feature height). Other feature geometries can instead or additionally be used.

Further non-active regions 1620a, 1620b, 1620c (collectively referred to as non-active regions 1620) are adjacent to and surrounding active regions 1618a, 1618b, 1618c (collectively referred to as active regions 1618), respectively. The non-active regions 1620 include respective non-active gratings with walls extending parallel to the local interfaces between the non-active regions 1620 and the active regions 1618. For example, circular active region 1618b has a circular interface 1622 with non-active region 1620b, and walls 1626 of a non-active grating 1624 of the non-active region 1620b extend circumferentially, parallel to the circular interface 1622.

In some implementations, this orientation can help maintain a smooth demolding and/or imprinting force and, as discussed above, space peel-off and/or non-fill zones away from active structures.

Respective non-active gratings of non-active regions 1620a, 1620c (not shown) can have characteristics as described for grating 1624. For example, walls of a non-active grating in non-active region 1620c can be shaped elliptically to surround and be locally parallel to an elliptically-shaped boundary between non-active region 1620c and elliptically-shaped active region 1618c; the walls of the non-active grating can be tiled radially with respect to a center of the active region 1618c. As another example, active region 1618a is rectangular, and non-active region 1620a can include four non-active gratings on four respective sides of the active region 1618a, with walls of each non-active grating extending parallel to the closest side of the active region 1618 and tiled/periodic in a direction orthogonal to the closest side.

Although non-active grating 1624 is shown as non-gradated, composed of walls with uniform heights, in some implementations a non-active grating having a circumferential configuration (e.g., circular or elliptical) can be gradated, e.g., in height, as described with respect to non-active grating 1606.

The non-active structures of the non-active regions 1620, and other non-active structures in the examples discussed herein, can include 1D lines and spaces/gratings, 2D mesh-like holes, pillars, and/or discontinuous lines/spaces, and/or 2D pillars/checkerboards (e.g., a grating composed of a 2D array of pillars and/or columns), to give several non-limiting examples. Various geometries, patterns, and arrangements of structure(s) in the non-active region are within the scope of this disclosure. The orientation of non-active gratings can be parallel, perpendicular, and/or or tilted with respect to the gratings in the active region, and can be parallel, perpendicular, and/or tiled with respect to imprinting and/or separation directions. In some implementations, the non-active structures can include several sections around the active region, and each section has different grating geometry, such as different non-active grating orientation and/or structure, in some combination in combination with gradation. The non-active gratings can not only help mitigate the shearing-caused grating delamination/damage, but, in some implementations, also can help to maintain enough resist for the residual layer under the grating, to reduce/prevent non-fill defects in the active region. For example, non-active grating 1606 can act as a barrier for fluid running off the active region 1602 due to capillary forces, helping reduce or eliminate defects in the active region 1602. The non-active region structures may instead or additionally pin, balance, spread-out, and/or reduce imprinting forces.

In some implementations in which active regions include slanted gratings, the shearing force associated with imprinting will be larger as the grating is tilted with respect to the imprint direction, such as when the slanted grating regions are in pinwheel positions and the orientation of the slanted gratings tilts with respect to the imprint direction. Non-active regions can be added adjacent to and/or surrounding the non-active regions having the slanted gratings, to move the separation edge to the non-active regions, thus helping to mitigate grating damages that would otherwise be initiated at the edge of the slanted gratings

For example, FIG. 17 shows a substrate 1700 on which are imprinted active regions 1702a-1702f (referred to collectively as active regions 1702). Imprinted structures on the substrate 1700 are formed in an imprinting process with imprint direction 1701, which is parallel to the separation direction. Each active region 1702 includes a slanted grating with a different orientation and tilt direction corresponding to a pinwheel arrangement of the slanted gratings. For example, the slanted gratings can be tiled outward from a central position 1704 of the pinwheel, and walls of the gratings can extend orthogonal to the tiling direction and can be tilted along the tiling direction (e.g., tilted towards or away from the central position 1704). For example, the slanted grating 1706 of active region 1702b has walls 1708 that extend parallel to the imprint direction 1701 (and separation), and the walls 1708 are tilted orthogonal to the imprint direction 1701 (toward the central position 1704 along a central direction 1714), not tilted along the imprint direction 1701 (or separation direction). This can result in relatively low shearing force for imprinting the slanted grating 1706. Features of the slanted grating 1706 extending parallel to the imprint direction 1701 as discussed for the walls 1614 of the grating 1612, and the same benefits as discussed for the grating 1612 can be obtained from this orientation.

However, the slanted grating 1710 of active region 1702d includes walls 1712 tilted along a central direction 1716 (towards the central position 1704) that is non-orthogonal with the imprint direction 1701. As such, the imprinting of slanted grating 1710 may be associated with a relatively high shearing force.

To mitigate this shearing force, as least one of the active regions 1702 (in this example, all active regions 1702) can be adjacent to and/or surrounded by a corresponding non-active region 1718 having a non-active grating. The non-active gratings can have configurations and orientations as described, for example, with respect to non-active regions 1620b, 1620c in reference to FIG. 16. The presence of the non-active grating regions (shown in green) surrounding each of the slanted grating regions (shown in yellow) can move the separation edge to the non-active regions, thus helping to mitigate grating damages initiated at the edge of the slanted gratings. In some implementations, the non-active gratings can be non-slanted to reduce shearing forces at boundaries of the non-active gratings.

The imprinted structures of non-active regions in each example described herein can include nanostructures, which can be, though need not be, composed of a nanostructure array, such as 1D gratings (e.g., lines/walls and spaces/trenches), 2D nanostructure arrays (e.g., pillars/holes/columns in an array), and/or 3D nanostructure arrays (e.g. multi-step pillars/holes with lines and spaces, etc., with periodicity or quasi-periodicity), without limitation to the particular structures described with respect to each example. The imprinted structures need not be periodic or quasi-periodic (e.g., periodic save for a gradation in feature height or another dimension), but, rather, in some cases can include non-periodic and/or random structures. For example, the imprinted structures of the non-active regions can include 1D, 2D, and/or 3D nanostructures without necessarily having periodicity. As noted above, in some implementations the imprinted non-active structures have a pitch between 20 nm and 200 nm or between 50 nm and 200 nm. Moreover, in some implementations the imprinted non-active structures have a line width between 10 nm and 150 nm, and/or a height between 10 nm and 300 nm. These dimensions have been found to provide benefits of structural integrity, reliability/ease of imprinting, and desired optical characteristics. However, in some implementations the imprinted non-active structures have different dimensions from those.

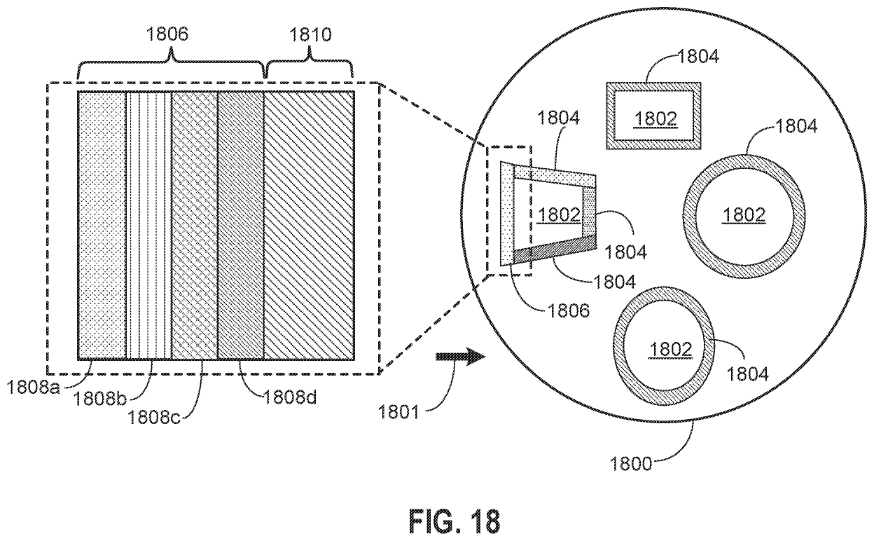

FIG. 18 illustrates another example of an imprinted structure. The structure is imprinted on a substrate 1800 and has characteristics as described in reference to the imprinted structures FIG. 16, except where noted otherwise. For example, active regions 1802 can have characteristics as described for the corresponding active regions 1602 and 1618a, 1618b, 1618c, and the adjacent non-active regions 1804 can have characteristics as described for non-active regions 1604b, 1604c, 1604d, 1620a, 1620b, and 1620c. Imprinted patterns are formed with an imprint direction 1801, which is parallel to the separation direction.

Non-active region 1806 includes multiple zones 1808a, 1808b, 1808c, 1808d (referred to collectively as zones 1808) having different respective non-active optical structures. Zone 1808d is adjacent to an active optical structure (e.g., grating) 1810 in the active region 1802. Non-active structures in the zones 1808, and/or the zones 1808 themselves (e.g., relative positions of the zones 1808) can be oriented such that imprinted structures change in a direction parallel to the imprint direction and/or demolding/separation direction. For example, the imprinted structures can change across the zones 1808 approaching the active optical structure 1810, e.g., a diffraction pattern on a waveguide, in a direction parallel to the imprint direction 1801. For example, as shown in FIG. 18, the zones 1808 can be oriented so that the imprint direction 1801 passes through multiple zones 1808 in succession; correspondingly, during some imprint processes to form the structures shown in FIG. 18, structures of the multiple zones 1808 will be formed by a template in succession, and the template will separate from each zone 1808 in succession. The different zones 1808 can have different structure densities, geometries, types, arrangements, and/or other characteristics.

For example, in some implementations, non-active optical structures of the zones 1808 have one or more dimensions that change from zone to zone in the imprint direction 1801. For example, one or more array parameters (e.g., feature height or depth, feature spacing, feature width, feature length, feature density, orientation (e.g., array angle with respect to a given direction), and/or array pitch and/or duty cycle in one or more dimensions) can be different for respective non-active (e.g., sub-diffractive) arrays in zones 1808a, 1808b, 1808c, 1808d, e.g., the array parameter can increase or decrease from zone 1808a, to 1808b, to 1808c, to 1808d, or from one or more of those zones to one or more adjacent ones (e.g., from zone 1808b to zone 1808c). In some implementations, the one or more array parameters change from zone to zone to approach a value of the same array parameter(s) in the active optical structure 1810. For example, when an array parameter in the active optical structure 1810 has value x₅, and the same array parameter in zones 1808a-1808d has values x₁-x₄, respectively, in some implementations the structures are configured such that x₁≤x₂≤x₃≤x₄≤x₅ or such that x₁≥x₂≥x₃≥x₄≥x₅.

For example, in some implementations, orientations of respective gratings of the zones 1808 change from zone to zone to approach an orientation of the active optical structure 1810. For example, the active optical structure 1810 can include a grating having walls oriented perpendicular to the imprint direction 1801, which may lead to defects at edges of the grating, e.g., due to high separation forces. Zone 1808d can have a non-active grating with an orientation close to that of the grating in the active optical structure 1810, but, in some cases, at least somewhat closer to parallel to the imprint direction 1801; a non-active grating in zone 1808c can be even more parallel to the imprint direction 1801; and so on, until zone 1808a includes a non-active grating that is parallel or substantially parallel to the imprint direction 1801. As such, imprinting and/or separation forces are gradually modulated/redirected to/from the active optical structure 1810, avoiding spatially-concentrated forces that may cause increased incidence of defects.

As another example, in some implementations the pattern fill factor (ratio of structure to empty space in an area) changes from zone to zone, which can (i) help reduce fluid spread, maintaining fluid in the active region, and/or (ii) facilitate a gradual demolding force going from the active optical structure 1810, through the zones 1808d, 1808c, 1808b, and 1808a, and to a region outside the non-active region 1806 (e.g., a blank region). For example, the fill factor can increase from zone 1808a to zone 1808b to zone 1808c to zone 1808d.

Although FIG. 18 illustrates four zones 1808, in some implementations a different number of zones, such as two, three, or more than four, can be provided. Moreover, in some implementations, a non-active region includes a single zone, e.g., as in the case of non-active region 1604c.

Optical elements including active regions and adjacent non-active regions may be utilized in head-mounted devices, such as AR, VR, XR, etc. headsets, such as those described in reference to FIGS. 1-12. For example, optical elements described in reference to FIGS. 1-12 can be formed by imprinting optical structures in an active region, and, as described above, imprinting a non-active region (e.g., adjacent to the active region) to reduce imprinting-related defects. For example, optical structures formed by imprinting in the described active regions (including, for example, gratings) can include out-coupling optical elements 570, 580, 590, 600, 610, in-coupling optical elements 1260, 1262, 1264, and/or another optical element, such as any suitable type of diffractive optical element (DOE), such as beam splitters, beam shapers, lenses, and/or diffusers. For example, the active optical structures can include diffractive optical elements disposed above or otherwise in proximity to a waveguide for light coupling to/from the waveguide, and the non-active structures can be non-diffractive or sub-diffractive structures adjacent to the active optical structures. Gratings described herein can include, for example, binary phase gratings, blazed gratings, and/or slanted gratings.

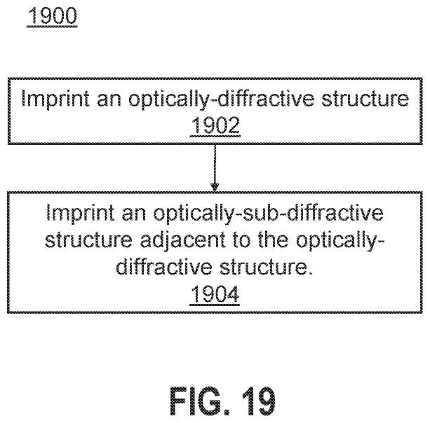

FIG. 19 illustrates an example of a process 1900 that can be performed according to some aspects of this disclosure. The process 1900 includes imprinting an optically-diffractive structure (1902) and imprinting an optically-sub-diffractive structure adjacent to the optically-diffractive structure (1904). For example, imprinting the two structures can be performed in a common imprinting process, e.g., using a common template that includes surface relief structures corresponding to both the optically-diffractive structure and the optically diffractive structure. The optically-diffractive structure can be any of the active optical structures discussed herein (e.g., in reference to FIGS. 13-18), and the optically-sub-diffractive structure can include any of the non-active structures, in regions adjacent to active optical regions, discussed herein.

As discussed above, because of the inclusion of the optically-sub-diffractive structure in the imprinting process(es) of process 1900, imprinting defects affecting the optically-diffractive structure, such as delamination and/or bubble formation, can be reduced or eliminated. As such, optical device performance can be improved.

Imprinting processes within the scope of this disclosure include at least nanoimprint lithography processes, such as thermoplastic nanoimprint lithography, photo nanoimprint lithography, and direct thermal nanoimprint lithography. Further examples of imprinting processes within the scope of this disclosure include micro-imprint processes. Imprinted structures, such as active optical structures and non-active (e.g., sub-diffractive) structures, can be formed in an imprint resist by mechanical deformation of the resist and subsequent processing, such as thermal and/or UV curing. A template mold is configured with a surface relief pattern that forms a corresponding pattern in the imprint resist. Imprinting processes within the scope of this disclosure include at least hard-mold, soft-mold, roll-to-roll, roll-to-plate, plate-to-roll, plate-to-plate, and hybrid nanoimprint processes.

Imprinting, such as imprinting in process 1900, can be performed using a template (e.g., a superstrate, a mold, a stamp, etc.), a substrate, and a formable material (sometimes referred to as a coating or imprint resist) disposed on the template and/or on the substrate. For example, the formable material can be provided on the template, the substrate, or both prior to imprinting. The formable material can include, for example, a polymer, an epoxy, a resin, a photoresist, a spin-on glass, or another material that can be structured in an imprinting process. In some implementations, the formable material is curable, e.g., by application of thermal energy, light (e.g., UV), and/or another stimulus. For example, the formable material can be cured subsequent to formation of structures in the formable material, and curing can occur while the template is in contact with the formable material, after removal of the template from the formable material, or both.

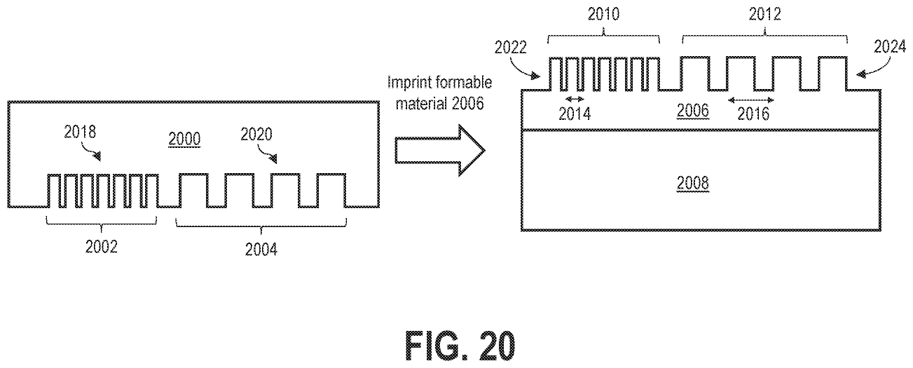

FIG. 20 illustrates an example of a template 2000 and corresponding imprinted structures. The template 2000 has a first set of surface relief structures 2020 in a first region 2004, and a second set of surface relief structures 2018 in a second region 2002; the two sets of surface relief structures 2018, 2020 are adjacent to one another. The template 2000 can be composed of, for example, an organic polymer, and/or an inorganic material such as a dielectric, metal, alloy, etc. The template 2000 can be rigid and/or flexible.

The template 2000 is used to imprint a formable material 2006 disposed on a substrate 2008. The formable material 2006 can include any of the types of formable material discussed above, such as a polymer, an epoxy, a resin, a photoresist, a spin-on glass, or another material that can be structured in an imprinting process.

Various types of the substrate 2008 are within the scope of this disclosure, including semiconductor, dielectric, organic (e.g., polymer or plastic), metal, etc. The substrate 2008 can be rigid and/or flexible. In some implementations, the substrate 2008 has a refractive index (e.g., for waveguides in the substrate 2008) in the range of 1.45 (e.g., corresponding to fused silica or quartz) to 2.7 (e.g., SiC). As noted above, the imprinting can be roll-to-roll, roll-to-plate, plate-to-roll, plate-to-plate, or another suitable imprinting process.

As a result of the imprinting, an optically-diffractive structure 2024 is formed in an active region 2012 of the formable material 2006, and an optically-sub-diffractive structure 2022 (in some implementations, a non-diffractive structure) is formed adjacent to the optically-diffractive structure 2024 in a non-active region 2010 of the formable material 2006. The imprinted structures 2022, 2024 are formed by and directly correspond to the sets of surface relief structures 2018, 2020 of the template 2000, e.g., having matching or inverse shapes and topography. For example, a pitch 2014 of the optically-sub-diffractive structure 2022 can be less than a pitch 2016 of the optically-diffractive structure 2024, based on a pitch (not shown) of the second set of surface relief structures 2018 being less than a pitch (not shown) of the first set of surface relief structures 2020. For example, in some implementations, the pitch 2014 is equal to the pitch of the second surface relief structure 2018, and the pitch 2016 is equal to the pitch of the first surface relief structure 2020.

The sets of surface relief structures 2018, 2020 can be configured (e.g., based on their topology) to imprint any of the combinations of adjacent active and non-active regions, or adjacent diffractive and sub-or non-diffractive structures, discussed herein. For example, the sets of surface relief structures 2018, 2020 can be adjacent to one another to cause the optically-diffractive structure 2024 and the optically-sub-diffractive structure 2022 to be adjacent to one another. Moreover, based on the correspondence between template structures and imprinted structures, the sets of surface relief structures 2018, 2020 can be any of the structures discussed herein for active and non-active structures, e.g., can include gratings, arrays, etc., with the dimensions and patterns discussed herein for active and non-active structures in reference to FIGS. 16-18.

In some implementations, the substrate 2008 include one or more waveguides (not shown) arranged to couple optically with the optically-diffractive structure 2024, e.g., for light in-coupling/out-coupling at one or more wavelengths. Light having the same wavelength(s) may not couple into or out of the waveguides via the optically-sub-diffractive structure 2022, based on dimension(s) of the optically-sub-diffractive structure 2022.

In the foregoing description, various examples of implementations have been described. It will, however, be evident that various modifications and changes may be made thereto without departing from the broader spirit and scope of this disclosure. The specification and drawings are, accordingly, to be regarded in an illustrative rather than restrictive sense.

Indeed, it will be appreciated that the systems and methods of the disclosure each have several innovative aspects, no single one of which is solely responsible or required for the desirable attributes disclosed herein. The various features and processes described above may be used independently of one another, or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations, one or more features from a described combination may in some cases be excised from the combination, and the described combination may be directed to a subcombination or variation of a subcombination. No single feature or group of features is necessary or indispensable to each and every embodiment.

It will be appreciated that conditional language used herein, such as, among others, “can,” “could,” “might,” “may,”“e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. In addition, the articles “a,” “an,” and “the” as used in this application are to be construed to mean “one or more” or “at least one” unless specified otherwise.

Moreover, the separation of various system components in the embodiments described above should not be understood as requiring such separation in all embodiments, and it should be understood that the described program components and systems may generally be integrated together.

Accordingly, the examples provided herein are not intended to be limited to the embodiments shown herein, but are to be accorded the widest scope consistent with this disclosure and the principles and novel features disclosed herein.

Examples of embodiments include at least the following.

Embodiment 1: A method, including: imprinting an optically-diffractive structure; and imprinting an optically-sub-diffractive structure adjacent to the optically-diffractive structure.

Embodiment 2: Embodiment 1, in which the optically-diffractive structure includes a first grating, in which the optically-sub-diffractive structure includes a second grating, and in which at least one geometrical feature differs between the first grating and the second grating.

Embodiment 3: Embodiment 2, in which the at least one geometrical feature includes at least one of grating orientation, pitch, width, height, or duty cycle.

Embodiment 4: Any of Embodiments 2-3, in which the second grating includes features that extend parallel to a separation direction of the imprinting.

Embodiment 5: Any of Embodiments 1-4, in which the optically-sub-diffractive structure includes multiple different structures in respective zones of a plurality of zones of the optically-sub-diffractive structure.

Embodiment 6: Embodiment 5, in which the multiple different structures are different in at least one of feature density or feature orientation.

Embodiment 7: Any of Embodiments 5-6, in which the plurality of zones are arranged along an imprint direction.

Embodiment 8: Any of Embodiments 1-7, in which the optically-sub-diffractive structure surrounds the optically-diffractive structure.

Embodiment 9: Any of Embodiments 1-8, in which the optically-sub-diffractive structure includes features having a gradated dimension, the gradated dimension increasing or decreasing in a direction toward the optically-diffractive structure.

Embodiment 10: Embodiment 9, in which the features include grating walls having heights that increase in the direction toward the optically-diffractive structure.

Embodiment 11: Any of Embodiments 1-10, in which the optically-sub-diffractive structure includes features having a gradated dimension, the gradated dimension increasing or decreasing in an imprint direction.

Embodiments 12: Any of Embodiments 1-11, in which imprinting the optically-diffractive structure and imprinting the optically-sub-diffractive structure are performed in a common imprinting process using a common template.

Embodiment 13: Any of Embodiments 1-12, in which the optically-diffractive structure includes a diffractive in-coupler to a waveguide or a diffractive out-coupler from the waveguide.

Embodiment 14: Any of Embodiments 1-13, in which the optically-sub-diffractive structure includes features extending circumferentially around the optically-diffractive structure.

Embodiment 15: Any of Embodiments 1-14, in which the optically-diffractive structure has a pitch between 200 nm and 1 μm, and in which the optically-sub-diffractive structure has a pitch between 20 nm and 200 nm.

Embodiment 16: Any of Embodiments 1-15, in which the optically-diffractive structure has a pitch that causes the optically-diffractive structure to interact diffractively with visible light, and in which the optically-sub-diffractive structure has a pitch that causes the optically-sub-diffractive structure to not interact diffractively with visible light.

Embodiment 17: Any of Embodiments 1-16, in which imprinting the optically-diffractive structure and the optically-sub-diffractive structure is performed in a roll-to-roll, roll-to-plate, plate-to-roll, or plate-to-plate process.

Embodiment 18: Any of Embodiments 1-17, in which the optically-sub-diffractive structure includes a one-dimensional grating, a two-dimensional nanostructure array, or a three-dimensional nanostructure array.

Embodiment 19: An optical device, including: a waveguide; an imprinted grating, the grating arranged to direct light into the waveguide or out of the waveguide; and an imprinted sub-diffractive structure arranged adjacent to the grating.

Embodiment 20: A display system, including: a waveguide; a light-coupling element including an imprinted grating; and an imprinted sub-diffractive structure arranged adjacent to the grating.

Embodiment 21: An imprinting template, including: a first set of surface relief structures configured to imprint an optically-diffractive structure in a formable material, and a second set of surface relief structures configured to imprint an optically-sub-diffractive structure in the formable material, in which the second set of surface relief structures are adjacent to the first set of surface relief structures.

Embodiment 22: An optical device, including an optically-diffractive structure and an optically-sub-diffractive structure, the optical device formed by any of Embodiments 1-18.

A number of embodiments have been described. Nevertheless, it will be understood that various modifications may be made. Elements of one or more embodiments may be combined, deleted, modified, or supplemented to form further embodiments. In yet another example, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

1. A method, comprising:
imprinting an optically-diffractive structure; and
imprinting an optically-sub-diffractive structure adjacent to the optically-diffractive structure.

2. The method of claim 1, wherein the optically-diffractive structure comprises a first grating,
wherein the optically-sub-diffractive structure comprises a second grating, and
wherein at least one geometrical feature differs between the first grating and the second grating.

3. The method of claim 2, wherein the at least one geometrical feature comprises at least one of grating orientation, pitch, width, height, or duty cycle.

4. The method of claim 2, wherein the second grating comprises features that extend parallel to a separation direction of the imprinting.

5. The method of claim 1, wherein the optically-sub-diffractive structure comprises multiple different structures in respective zones of a plurality of zones of the optically-sub-diffractive structure.

6. The method of claim 5, wherein the multiple different structures are different in at least one of feature density or feature orientation.

7. The method of claim 5, wherein the plurality of zones are arranged along an imprint direction.

8. The method of claim 1, wherein the optically-sub-diffractive structure surrounds the optically-diffractive structure.

9. The method of claim 1, wherein the optically-sub-diffractive structure comprises features having a gradated dimension, the gradated dimension increasing or decreasing in a direction toward the optically-diffractive structure.

10. The method of claim 9, wherein the features comprise grating walls having heights that increase in the direction toward the optically-diffractive structure.

11. The method of claim 1, wherein the optically-sub-diffractive structure comprises features having a gradated dimension, the gradated dimension increasing or decreasing in an imprint direction.

12. The method of claim 1, wherein imprinting the optically-diffractive structure and imprinting the optically-sub-diffractive structure are performed in a common imprinting process using a common template.

13. The method of claim 1, wherein the optically-diffractive structure comprises a diffractive in-coupler to a waveguide or a diffractive out-coupler from the waveguide.

14. The method of claim 1, wherein the optically-sub-diffractive structure comprises features extending circumferentially around the optically-diffractive structure.

15. The method of claim 1, wherein the optically-diffractive structure has a pitch between 200 nm and 1 μm, and
wherein the optically-sub-diffractive structure has a pitch between 20 nm and 200 nm.

16. The method of claim 1, wherein the optically-diffractive structure has a pitch that causes the optically-diffractive structure to interact diffractively with visible light, and
wherein the optically-sub-diffractive structure has a pitch that causes the optically-sub-diffractive structure to not interact diffractively with visible light.

17. The method of claim 1, wherein imprinting the optically-diffractive structure and the optically-sub-diffractive structure is performed in a roll-to-roll, roll-to-plate, plate-to-roll, or plate-to-plate process.

18. The method of claim 1, wherein the optically-sub-diffractive structure comprises a one-dimensional grating, a two-dimensional nanostructure array, or a three-dimensional nanostructure array.

19. An optical device, comprising:
a waveguide;
an imprinted grating, the grating arranged to direct light into the waveguide or out of the waveguide; and
an imprinted sub-diffractive structure arranged adjacent to the grating.

20. A display system, comprising:
a waveguide;
a light-coupling element comprising an imprinted grating; and
an imprinted sub-diffractive structure arranged adjacent to the grating.
